(19) United States
(12) Patent Application Publication
(10) Pub. No.: US 2023/0009932 A1
(43) Pub. Date: Jan. 12, 2023

(54) SEMICONDUCTOR DEVICE AND ELECTRONIC SYSTEM INCLUDING THE SAME

(71) Applicant: SAMSUNG ELECTRONICS CO., LTD., Suwon-si (KR)

(72) Inventors: Sunyoung LEE, Hwaseong-si (KR); Shinhwan KANG, Suwon-si (KR); Seokcheon BAEK, Hwaseong-si (KR)

(21) Appl. No.: 17/838,575

(22) Filed: Jun. 13, 2022

(30) Foreign Application Priority Data
Jul. 7, 2021 (KR) 10-2021-0089157

(51) Int. Cl. H01L 23/00; H01L 23/535; H01L 27/11556; H01L 27/11529; H01L 27/11582; H01L 27/11573

(52) U.S. Cl. CPC H01L 23/562; H01L 23/535; H01L 27/11529; H01L 27/11556; H01L 27/11573; H01L 27/11582

(57) ABSTRACT

A semiconductor device including a substrate including first, second, and third regions; a peripheral circuit structure on the substrate and including a peripheral circuit and wiring layers connected to the peripheral circuit; a common source plate on the peripheral circuit structure and extending in a horizontal direction; gate electrodes on the common source plate on the first and second regions, spaced apart from each other in a first direction perpendicular to an upper surface of the substrate, the gate electrodes having a stair shape on the second region; a channel structure extending in the first direction through the gate electrodes on the first region; a first conductive through-via penetrating the common source plate on the third region and electrically connected to the wiring layers; and a dummy insulating pillar adjacent to the first conductive through-via on the third region and connected to an upper surface of the common source plate.

### CROSS-REFERENCE TO RELATED APPLICATION

This application is based on and claims priority under 35 U.S.C. §119 to Korean Patent Application No. 10-2021-0089157, filed on Jul. 7, 2021, in the Korean Intellectual Property Office, the disclosure of which is incorporated by reference herein in its entirety.

### BACKGROUND

### 1. Field

Embodiments relate to a semiconductor device and an electronic system including the same.

### 2. Description of the Related Art

In an electronic system requiring data storage, a semiconductor device capable of storing high-capacity data may be used. The data storage capacity of a semiconductor device may be increased.

### SUMMARY

The embodiments may be realized by providing a semiconductor device including a substrate including a first region, a second region, and a third region; a peripheral circuit structure on the substrate and including a peripheral circuit and a plurality of wiring layers connected to the peripheral circuit; a common source plate on the peripheral circuit structure and extending in a horizontal direction; gate electrodes on the common source plate on the first region and the second region, spaced apart from each other in a first direction perpendicular to an upper surface of the substrate, the gate electrodes having a stair shape on the second region; a channel structure extending in the first direction through the gate electrodes on the first region; a first conductive through-via penetrating the common source plate on the third region and electrically connected to the plurality of wiring layers; and a dummy insulating pillar adjacent to the first conductive through-via on the third region and connected to an upper surface of the common source plate.

The embodiments may be realized by providing a semiconductor device including a substrate including a first region, a second region, and a third region; a peripheral circuit structure on the substrate, the peripheral circuit structure including a peripheral circuit and a plurality of wiring layers connected to the peripheral circuit; a common source plate on the peripheral circuit structure, extending in a horizontal direction, and including an opening on the third region; an insulating plug filling an inside of the opening of the common source plate; gate electrodes on the common source plate on the first region and the second region, spaced apart from each other in a first direction perpendicular to an upper surface of the substrate, and having a stair shape on the second region; a cover insulating layer on the second region and the third region, the cover insulating layer covering portions of the gate electrodes having a stair shape on the second region; a first conductive through-via in a first through-hole penetrating the cover insulating layer and the insulating plug on the third region and electrically connected to the plurality of wiring layers; a second conductive through-via adjacent to the first conductive through-via on the third region and in a second through-hole penetrating the cover insulating layer and the insulating plug; and a dummy insulating pillar adjacent to the first conductive through-via on the third region, in a dummy through hole penetrating the cover insulating layer, and having a bottom on an upper surface of the common source plate.

The embodiments may be realized by providing an electronic system including a main board; a semiconductor device on the main board; and a controller electrically connected to the semiconductor device on the main board, wherein the semiconductor device includes a substrate including a first region, a second region, and a third region, a peripheral circuit structure on the substrate, the peripheral circuit structure including a peripheral circuit and a plurality of wiring layers connected to the peripheral circuit, a common source plate on the peripheral circuit structure and extending in a horizontal direction, gate electrodes on the common source plate on the first region and the second region, spaced apart from each other in a first direction perpendicular to an upper surface of the substrate, and having a stair shape on the second region, a channel structure extending in the first direction through the gate electrodes on the first region, a first conductive through-via penetrating the common source plate on the third region and electrically connected to the plurality of wiring layers, and a dummy insulating pillar adjacent to the first conductive through-via on the third region and connected to an upper surface of the common source plate.

### BRIEF DESCRIPTION OF THE DRAWINGS

Features will be apparent to those of ordinary skill in the art by describing in detail exemplary embodiments with reference to the attached drawings in which:

FIG. 1 is a block diagram of a semiconductor device according to exemplary embodiments;

FIG. 2 is an equivalent circuit diagram of a memory cell array of a semiconductor device according to exemplary embodiments;

FIG. 3 is a perspective view of a typical configuration of a semiconductor device according to exemplary embodiments;

FIG. 4 is a plan view of the semiconductor device of FIG. 3;

FIG. 5 is a cross-sectional view taken along line A-A′ of FIG. 4;

FIG. 6 is an enlarged view of a portion CX1 of FIG. 4;

FIG. 7 is an enlarged view of a portion CX2 of FIG. 5;

FIG. 8 is an enlarged view of a portion CX3 of FIG. 5;

FIG. 9 is a plan view of a semiconductor device according to exemplary embodiments;

FIG. 10 is a cross-sectional view of the semiconductor device of FIG. 9;

FIG. 11 is a cross-sectional view of a semiconductor device according to exemplary embodiments;

FIG. 12 is a cross-sectional view of a semiconductor device according to exemplary embodiments;

FIG. 13 is a cross-sectional view of a semiconductor device according to exemplary embodiments;

FIG. 14 is an enlarged view of a portion CX3 of FIG. 13;

FIG. 15 is a cross-sectional view of a semiconductor device according to exemplary embodiments;

FIGS. 16 to 32 are cross-sectional views of stages in a method of manufacturing a semiconductor device according to exemplary embodiments;

FIG. 33 is a schematic diagram of a data storage system including a semiconductor device according to exemplary embodiments;

FIG. 34 is a perspective view of a data storage system including a semiconductor device according to exemplary embodiments; and

FIG. 35 is a cross-sectional view of semiconductor packages according to exemplary embodiments.

### DETAILED DESCRIPTION

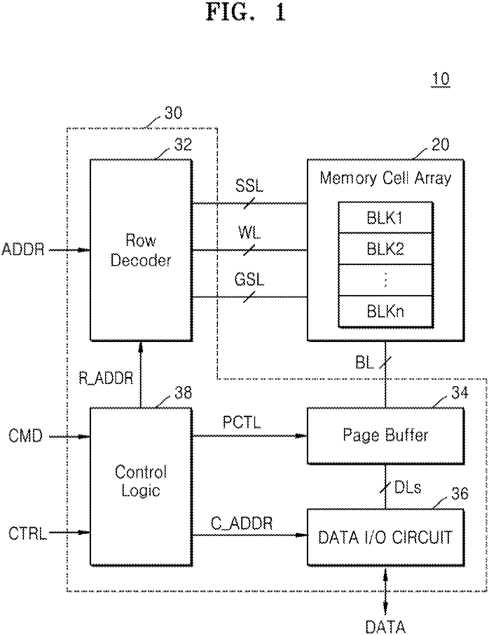

FIG. 1 is a block diagram of a semiconductor device 10 according to exemplary embodiments.

Referring to FIG. 1, the semiconductor device 10 may include a memory cell array 20 and a peripheral circuit 30. The memory cell array 20 may include a plurality of memory cell blocks BLK1, BLK2, ..., BLKn. Each of the plurality of memory cell blocks BLK1, BLK2, ..., BLKn may include a plurality of memory cells. The memory cell blocks BLK1, BLK2, ..., BLKn may be connected to the peripheral circuit 30 through a bit line BL, a word line WL, a string select line SSL, and a ground select line GSL.

The peripheral circuit 30 may include a row decoder 32, a page buffer 34, a data input/output (I/O) circuit 36, and a control logic 38. In an implementation, the peripheral circuit 30 may further include an I/O interface, column logic, a voltage generator, a predecoder, a temperature sensor, a command decoder, an address decoder, an amplifier circuit, or the like.

The memory cell array 20 may be connected to the page buffer 34 through the bit line BL, and may be connected to the row decoder 32 through the word line WL, the string select line SSL, and the ground select line GSL. In the memory cell array 20, each of the plurality of memory cells included in the plurality of memory cell blocks BLK1, BLK2, ..., BLKn may be a flash memory cell. The memory cell array 20 may include a three-dimensional memory cell array. The three-dimensional memory cell array may include a plurality of NAND strings, and each NAND string may include a plurality of memory cells connected to a plurality of word lines WL stacked vertically on a substrate.

The peripheral circuit 30 may receive an address ADDR, a command CMD, and a control signal CTRL from the outside of the semiconductor device 10, and may transmit/receive data DATA to and from an external device of the semiconductor device 10.

The row decoder 32 may select at least one of the plurality of memory cell blocks BLK1, BLK2, ..., BLKn in response to an address ADDR from the outside, and may select a word line WL, a string select line SSL, and a ground select line GSL of the selected memory cell block. The row decoder 32 may transmit a voltage for performing a memory operation to the word line WL of the selected memory cell block.

The page buffer 34 may be connected to the memory cell array 20 through the bit line BL. The page buffer 34 may operate as a write driver during a program operation to apply a voltage according to the data DATA to be stored in the memory cell array 20 to the bit line BL, and may operate as a sense amplifier during a read operation to sense data DATA stored in the memory cell array 20. The page buffer 34 may operate according to a control signal PCTL provided from the control logic 38.

The data I/O circuit 36 may be connected to the page buffer 34 through data lines DLs. The data I/O circuit 36 may receive data DATA from a memory controller during a program operation, and may provide the program data DATA to the page buffer 34 based on the column address C_ADDR provided from the control logic 38. The data I/O circuit 36 may provide the read data DATA stored in the page buffer 34 to the memory controller based on the column address C_ADDR provided from the control logic 38 during a read operation.

The data I/O circuit 36 may transmit an input address or command to the control logic 38 or the row decoder 32. The peripheral circuit 30 may further include an Electro Static Discharge (ESD) circuit and a pull-up/pull-down driver.

The control logic 38 may receive a command CMD and a control signal CTRL from the memory controller. The control logic 38 may provide the row address R_ADDR to the row decoder 32 and provide the column address C_ADDR to the data I/O circuit 36. The control logic 38 may generate various internal control signals used in the semiconductor device 10 in response to the control signal CTRL. In an implementation, the control logic 38 may adjust the voltage level provided to the word line WL and the bit line BL when a memory operation such as a program operation or an erase operation is performed.

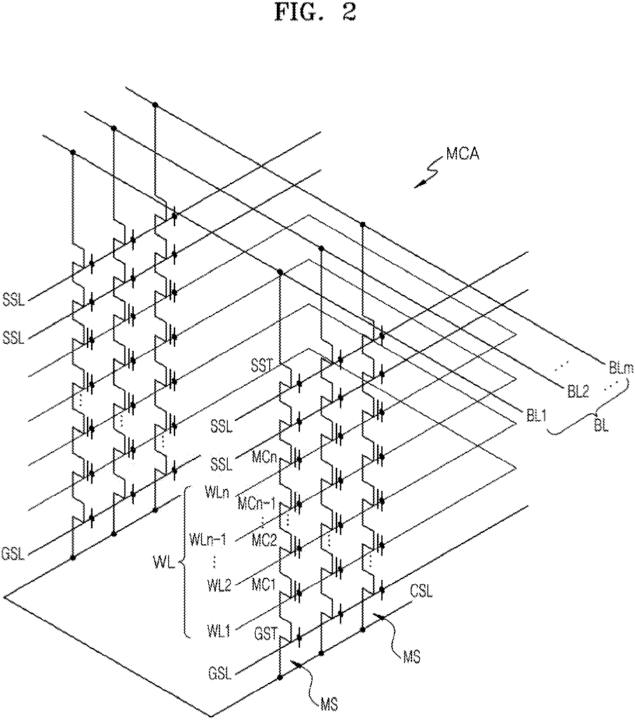

FIG. 2 is an equivalent circuit diagram of a memory cell array of the semiconductor device 10 according to exemplary embodiments.

Referring to FIG. 2, the memory cell array MCA may include a plurality of memory cell strings MS. The memory cell array MCA includes a plurality of bit lines BL1, BL2, ..., BLm (collectively referred to as “BL”), a plurality of word lines WL1, WL2, ..., WLn-1, WLn (collectively referred to as “WL”), at least one string select line SSL, at least one ground select line GSL, and a common source line CSL. A plurality of memory cell strings MS may be between the plurality of bit lines BL1, BL2, ..., BLm and the common source line CSL. In an implementation, as illustrated in FIG. 2, the plurality of memory cell strings MS each include two string select lines SSL. In an implementation, each of the plurality of memory cell strings MS may include one string select line SSL.

Each of the plurality of memory cell strings MS may include a string select transistor SST, a ground select transistor GST, and a plurality of memory cell transistors MC1, MC2, ..., MCn-1, MCn. A drain region of the string select transistor SST may be connected to bit lines BL1, BL2, ..., BLm, and a source region of the ground select transistor GST may be connected to a common source line CSL. The common source line CSL may be a region in which the source regions of the plurality of ground select transistors GST are commonly connected.

The string select transistor SST may be connected to the string select line SSL, and the ground select transistor GST may be connected to the ground select line GSL. The plurality of memory cell transistors MC1, MC2, ..., MCn-1, and MCn may be respectively connected to a plurality of word lines WL1, WL2, ..., WLn-1, WLn.

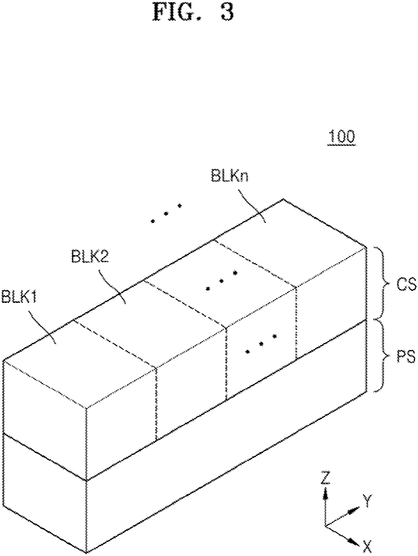

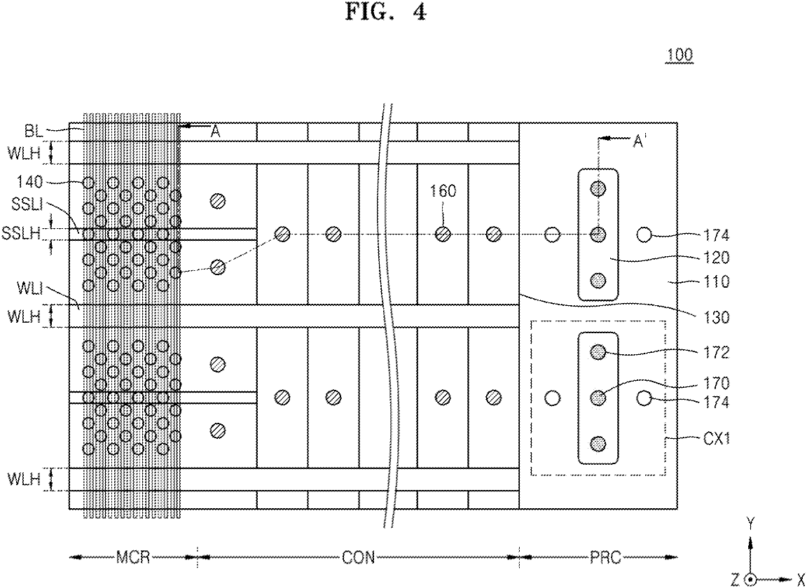

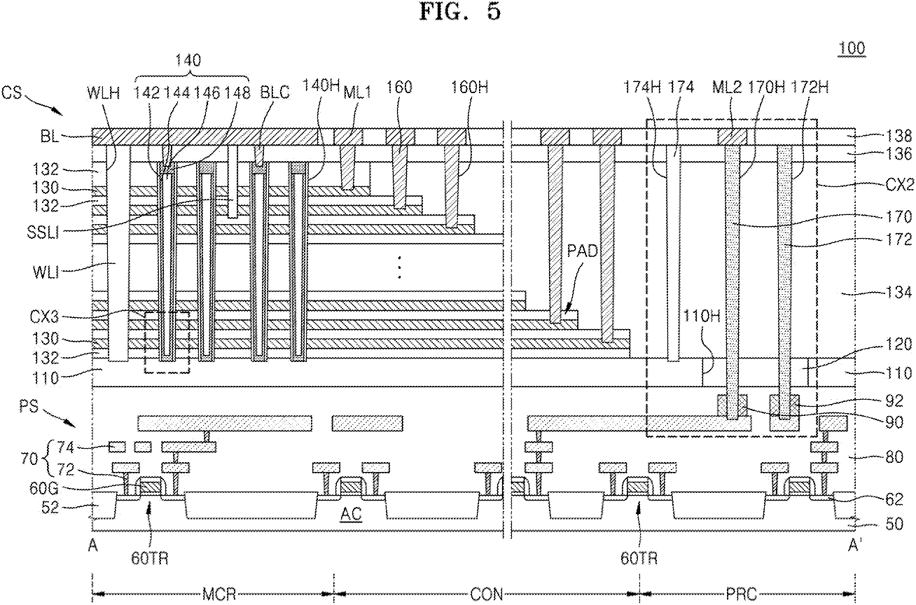

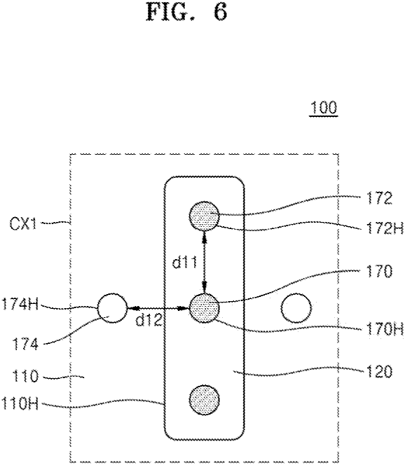

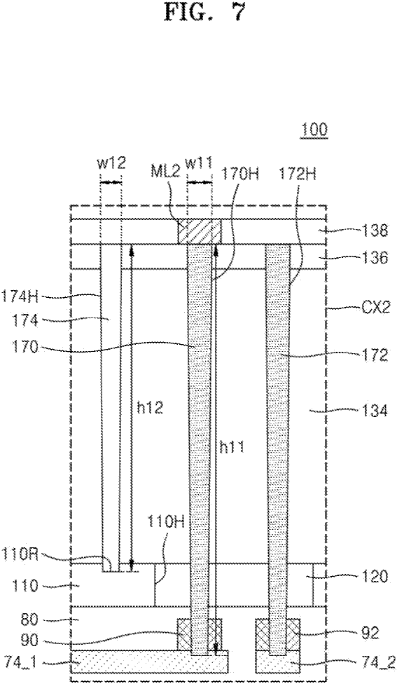

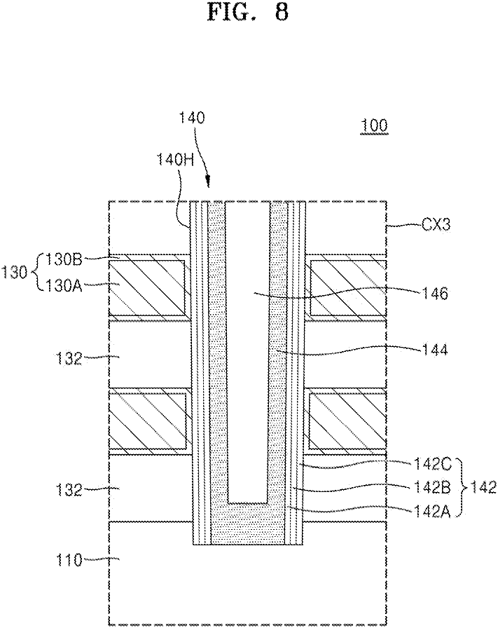

FIGS. 3 to 8 are diagrams of the semiconductor device 100 according to exemplary embodiments. Specifically, FIG. 3 is a perspective view of a typical configuration of the semiconductor device 100 according to exemplary embodiments, and FIG. 4 is a plan view of the semiconductor device 100 of FIG. 3. FIG. 5 is a cross-sectional view taken along line A-A′ of FIG. 4. FIG. 6 is an enlarged view of a portion CX1 of FIG. 4, FIG. 7 is an enlarged view of a portion CX2 of FIG. 5, and FIG. 8 is an enlarged view of part CX3 of FIG. 5.

Referring to FIGS. 3 to 8, the semiconductor device 100 may include a cell array structure CS and a peripheral circuit structure PS overlapping each other in the vertical direction Z. The cell array structure CS may include the memory cell array 20 described with reference to FIG. 1, and the peripheral circuit structure PS may include the peripheral circuit 30 described with reference to FIG. 1.

The memory cell array 20 may include a plurality of memory cell blocks BLK1, BLK2, ..., BLKn. Each of the plurality of memory cell blocks BLK1, BLK2, ..., BLKn may include three-dimensionally arranged memory cells.

The peripheral circuit structure PS may include a peripheral circuit transistor 60TR and a peripheral circuit wiring structure 70 on the substrate 50. The substrate 50 may include a horizontally arranged memory cell region MCR, a connection region CON, and a peripheral circuit connection region PRC. In the substrate 50, an active region AC may be defined by the device isolation layer 52, and a plurality of peripheral circuit transistors 60TR may be formed on the active region AC. The plurality of peripheral circuit transistors 60TR may include a peripheral circuit gate 60G and a source/drain region 62 in a portion of the substrate 50 on or at both sides of the peripheral circuit gate 60G.

The substrate 50 may include a semiconductor material, e.g., a group IV semiconductor, a group III-V compound semiconductor, or a group II-VI oxide semiconductor. In an implementation, the group IV semiconductor may include silicon (Si), germanium (Ge), or silicon-germanium. As used herein, the term “or” is not an exclusive term, e.g., “A or B” would include A, B, or A and B. The substrate 50 may be provided as a bulk wafer or as an epitaxial layer. In an implementation, the substrate 50 may include a silicon-on-insulator (SOI) substrate or a germanium-on-insulator (GeOI) substrate.

The peripheral circuit wiring structure 70 may include a plurality of peripheral circuit contacts 72 and a plurality of peripheral circuit wiring layers 74. An interlayer insulating layer 80 covering the peripheral circuit transistor 60TR and the peripheral circuit wiring structure 70 may be on the substrate 50. The plurality of peripheral circuit wiring layers 74 may have a multilayer structure including a plurality of metal layers arranged at different vertical levels.

A common source plate 110 may be on the interlayer insulating layer 80. In an implementation, the common source plate 110 may function as a source region supplying current to vertical memory cells formed in the cell array structure CS. The common source plate 110 may be on the memory cell region MCR, the connection region CON, and the peripheral circuit connection region PRC of the substrate 50.

In an implementation, the common source plate 110 may include, e.g., silicon (Si), germanium (Ge), silicon germanium (SiGe), gallium arsenide (GaAs), indium gallium arsenide (InGaAs), aluminum gallium arsenide (AlGaAs), or mixtures thereof. In an implementation, the common source plate 110 may include a semiconductor doped with an n-type impurity. In an implementation, the common source plate 110 may have a crystal structure, e.g., single crystal, amorphous, or polycrystalline. In an implementation, the common source plate 110 may include polysilicon doped with n-type impurities.

The common source plate 110 may include an opening 110H on a peripheral circuit connection region PRC of the substrate 50, and the insulating plug 120 may fill the inside of the opening 110H of the common source plate 110. The insulating plug 120 may have an upper surface at the same level as (e.g., coplanar with) an upper surface of the common source plate 110.

A plurality of gate electrodes 130 and a plurality of mold insulating layers 132 may be alternately arranged along the vertical direction Z on the common source plate 110 on the memory cell region MCR and the connection region CON. In an implementation, a first mold insulating layer 132 of the plurality of mold insulating layers 132 may be between the common source plate 110 and the lowermost gate electrode 130, a second mold insulating layer 132 of the plurality of mold insulating layers 132 may be between two adjacent gate electrodes 130, and a third mold insulating layer 132 among the plurality of mold insulating layers 132 may be on the uppermost gate electrode 130. In an implementation, the thickness of the first mold insulating layer 132 and the thickness of the third mold insulating layer 132 may be greater than the thickness of the second mold insulating layer 132.

In an implementation, as shown in FIG. 8, the gate electrode 130 may include a buried conductive layer 130A and a conductive barrier layer 130B surrounding upper, bottom, and side surfaces of the buried conductive layer 130A. In an implementation, the buried conductive layer 130A may include, e.g., a metal such as tungsten, nickel, cobalt, tantalum, or the like, a metal silicide such as tungsten silicide, nickel silicide, cobalt silicide, tantalum silicide, or the like, doped polysilicon, or a combination thereof. In an implementation, the conductive barrier layer 130B may include titanium nitride, tantalum nitride, tungsten nitride, or a combination thereof. In an implementation, a dielectric liner may be further arranged between the conductive barrier layer 130B and the mold insulating layer 132, and the dielectric liner may include a high dielectric material such as aluminum oxide.

In an implementation, the plurality of gate electrodes 130 may correspond to a ground select line GSL, a word line WL, and at least one string select line SSL constituting the memory cell string MS (refer to FIG. 2). In an implementation, the lowermost gate electrode 130 may function as a ground select line GSL, the uppermost two gate electrodes 130 may function as string select lines SSL, and the remaining gate electrodes 130 may function as word lines WL. Accordingly, a memory cell string MS in which the ground select transistor GST, the string select transistor SST, and the memory cell transistors MC1, MC2, ..., MCn-1, MCn therebetween are connected in series may be provided. In an implementation, at least one of the gate electrodes 130 may function as a dummy word line.

In an implementation, as shown in FIG. 4, a plurality of gate stack separation openings WLH may extend along the first horizontal direction X parallel to the upper surface of the common source plate 110 on the common source plate 110. A plurality of gate electrodes 130 between a pair of gate stack separation openings WLH may constitute one block. A first block BLK1 and a second block BLK2 are exemplarily illustrated in FIG. 3.

A gate stack separation insulating layer WLI (filling the inside of the gate stack separation opening WLH) may be on the common source plate 110. The gate stack separation insulating layer WLI may be formed of a silicon oxide film, a silicon nitride film, SiON, SiOCN, SiCN, or a combination thereof.

The plurality of channel structures 140 may penetrate the plurality of gate electrodes 130 and the plurality of mold insulating layers 132 from the upper surface of the common source plate 110 and extend in the vertical direction (Z direction) on the memory cell region MCR. The plurality of channel structures 140 may be spaced apart from each other at predetermined intervals in the first horizontal direction X, the second horizontal direction Y, and a third horizontal direction (e.g., a diagonal direction). The plurality of channel structures 140 may be arranged in a zigzag shape or a staggered shape.

Each of the plurality of channel structures 140 may be in the channel hole 140H on the memory cell region MCR. Each of the plurality of channel structures 140 may include a gate insulating layer 142, a channel layer 144, a buried insulating layer 146, and a conductive plug 148. The gate insulating layer 142 and the channel layer 144 may be sequentially (e.g., inwardly) arranged on a sidewall of the channel hole 140H. In an implementation, the gate insulating layer 142 may be conformally on the sidewall of the channel hole 140H, and the channel layer 144 may be conformally on the (e.g., inner) sidewall and the bottom of the channel hole 140H. The buried insulating layer 146 (filling the remaining space of the channel hole 140H) may be on the channel layer 144. The conductive plug 148 may be on the upper side of the channel hole 140H to contact the channel layer 144 and block the entrance of the channel hole 140H. In an implementation, the buried insulating layer 146 may be omitted, and the channel layer 144 may be formed in a pillar shape that fills the remaining portion of the channel hole 140H.

In an implementation, the channel layer 144 may be at the bottom of the channel hole 140H to contact (e.g., the upper surface of) the common source plate 110. In an implementation, as shown in FIG. 4, the bottom surface of the channel layer 144 may be arranged at a lower vertical level than the upper surface of the common source plate 110 (e.g., the channel layer 144 may partially penetrate into the common source plate 110).

In an implementation, as shown in FIG. 8, the gate insulating layer 142 may have a structure including a tunneling dielectric film 142A, a charge storage film 142B, and a blocking dielectric film 142C sequentially on an outer wall of the channel layer 144. Relative thicknesses of the tunneling dielectric film 142A, the charge storage film 142B, and the blocking dielectric film 142C constituting the gate insulating layer 142 may be variously modified.

The tunneling dielectric film 142A may include silicon oxide, hafnium oxide, aluminum oxide, zirconium oxide, tantalum oxide, or the like. The charge storage film 142B may be a region in which electrons penetrating the tunneling dielectric film 142A from the channel layer 144 may be stored, and may include silicon nitride, boron nitride, silicon boron nitride, or polysilicon doped with impurities. The blocking dielectric film 142C may be formed of silicon oxide, silicon nitride, or metal oxide having a higher dielectric constant than silicon oxide. The metal oxide may be formed of hafnium oxide, aluminum oxide, zirconium oxide, tantalum oxide, or a combination thereof.

In one block, the uppermost two gate electrodes 130 may be separated into two parts laterally by a string separation opening SSLH. A string separation insulating layer SSLI may be within the string separation opening SSLH, and the two parts may be spaced apart from each other in the second horizontal direction Y with a string separation insulating layer SSLI therebetween. The two parts may constitute the string select line SSL described with reference to FIG. 2.

The plurality of gate electrodes 130 on the connection region CON may constitute the pad portion PAD. As the plurality of gate electrodes 130 move away from the upper surface of the common source plate 110 in the connection region CON, they may extend to have a shorter length in the first horizontal direction X. Portions of the gate electrode 130 arranged in a stair shape may be referred to as the pad portion PAD. A cover insulating layer 134 may be on the portion of the gate electrode 130 constituting the pad portion PAD.

In an implementation, a plurality of dummy channel structures extending in the vertical direction Z through the plurality of gate electrodes 130 and the plurality of mold insulating layers 132 from the upper surface of the common source plate 110 may be further formed in the connection region CON. The dummy channel structure may help reduce or prevent leaning or bending of the gate electrode 130 in the manufacturing process of the semiconductor device 100 and may help secure structural stability. Each of the plurality of dummy channel structures may have a structure and shape similar to that of the plurality of channel structures 140. A first upper insulating layer 136 may be on the uppermost mold insulating layer 132 and the cover insulating layer 134.

A cell contact plug 160 (connected to the gate electrode 130 through the first upper insulating layer 136 and the cover insulating layer 134) may be on the connection region CON. The cell contact plug 160 may be inside the cell contact hole 160H penetrating the first upper insulating layer 136 and the cover insulating layer 134.

A first through hole 170H (penetrating the insulating plug 120, the cover insulating layer 134, and the first upper insulating layer 136) may be on the peripheral circuit connection region PRC, and a first conductive through-via 170 may be in the first through-hole 170H. In an implementation, the first conductive through-via 170 may include tungsten, titanium, tantalum, copper, aluminum, titanium nitride, tantalum nitride, tungsten nitride, or a combination thereof.

The first conductive landing via 90 may surround a bottom sidewall of the first conductive through-via 170, and may be covered by the interlayer insulating layer 80. A bottom surface of the first conductive landing via 90 may contact an upper surface of the first wiring layer 74_1 (refer to FIG. 7) of the peripheral circuit wiring layers 74. The first conductive landing via 90 may include polysilicon doped with n-type impurities.

In an implementation, as shown in FIG. 5, the first conductive landing via 90 may surround the sidewall of the first conductive through-via 170, and the bottom surface of the first conductive through-via 170 may contact the upper surface of the first wiring layer 74_1, or the bottom surface of the first conductive through-via 170 may contact an upper surface of the first conductive landing via 90, and the bottom surface of the first conductive landing via 90 may contact the upper surface of the first wiring layer 74_1.

A second conductive through-via 172 may be adjacent to the first conductive through-via 170 on the peripheral circuit connection region PRC. In an implementation, the second through hole 172H may be adjacent to the first through hole 170H and may pass through the insulating plug 120, the cover insulating layer 134, and the first upper insulating layer 136, and the second conductive through-via 172 may be in the second through hole 172H.

The second conductive landing via 92 may surround a bottom sidewall of the second conductive through-via 172, and may be covered by the interlayer insulating layer 80. A bottom surface of the second conductive landing via 92 may contact an upper surface of the second wiring layer 74_2 among the peripheral circuit wiring layers 74. The first and second conductive landing vias 90 and 92 may include polysilicon doped with n-type impurities.

The first conductive through-via 170 may be connected to the peripheral circuit transistor 60T through the first conductive landing via 90 and the first wiring layer 74_1. The second conductive through-via 172 may be grounded or floated through the second conductive landing via 92 and the second wiring layer 74_2.

A dummy insulating pillar 174 may be adjacent to the first conductive through-via 170 on the peripheral circuit connection region PRC. In an implementation, a dummy through hole 174H may be adjacent to the first through hole 170H and may penetrate the cover insulating layer 134 and the first upper insulating layer 136, and a dummy insulating pillar 174 may be in the dummy through hole 174H. The common source plate 110 may be exposed at the bottom of the dummy through hole 174H. In an implementation, a recess portion 110R may be in the common source plate 110 at the bottom of the dummy through hole 174H, and a bottom surface of the dummy insulating pillar 174 (filling the recess portion 110R) may be at a level lower (e.g., closer to the substrate 50 in the Z direction) than the upper surface of the common source plate 110.

In an implementation, the dummy insulating pillar 174 may include silicon oxide and may be formed of or as a continuous material layer continuously filling the dummy through hole 174H. In an implementation, the bottom surface of the dummy insulating pillar 174 may directly contact the recess portion 110R of the common source plate 110.

As shown in FIG. 7, the first conductive through-via 170 may have a first height h11 in the vertical direction Z, and the dummy insulating pillar 174 may have a second height h12 smaller than the first height h11 in the vertical direction Z. In an implementation, the second height h12 may be greater than or equal to 90% of the first height h11 and less than 100% of the first height h11. The first conductive through-via 170 may have a first width w11 in the first horizontal direction X on or at the upper surface thereof, and the dummy insulating pillar 174 may have a second width w12 smaller than the first width w11 in the first horizontal direction X on or at the upper surface thereof. In an implementation, the second width w12 may be greater than or equal to 90% of the first width w11 and less than 100% of the first width w11.

In an implementation, as shown in FIG. 6, at least one second conductive through-via 172 and at least one dummy insulating pillar 174 may be arranged around the first conductive through-via 170, and a separation distance d11 between the first conductive through-via 170 and the second conductive through-via 172 may be approximately similar or about equal to a separation distance d12 between the first conductive through-via 170 and the dummy insulating pillar 174. In an implementation, the number of the second conductive through-vias 172 and the dummy insulating pillars 174 or the separation distances d11 and d12 may vary.

On the memory cell region MCR, the bit line contact BLC may penetrate the first upper insulating layer 136 to contact the conductive plug 148 of the channel structure 140, and the bit line BL may be on the bit line contact BLC. A second upper insulating layer 138 covering a sidewall of the bit line BL may be on the first upper insulating layer 136.

A first wiring line ML1 may be on the cell contact plug 160 in the connection region CON, and a second wiring line ML2 may be on the first conductive through-via 170 in the peripheral circuit connection region PRC. As mentioned above, the second conductive through-via 172 is floated or grounded, a wiring line may not be on the second conductive through-via 172, and an upper surface of the second conductive through-via 172 may be covered by the second upper insulating layer 138. In an implementation, an upper surface of the dummy insulating pillar 174 may also be covered by the second upper insulating layer 138.

In some devices, first conductive through-vias on a peripheral circuit connection region may be formed in a relatively small number, or may have a relatively large separation distance from the adjacent first conductive through-via. In this case, in the etching process for forming a first through-hole, the etching depth of the first through-hole may be smaller than the target depth, and a not-open defect in which the upper surface of the first conductive landing via is not exposed could occur. In order to help prevent this, a second conductive through-via serving as a dummy through-via may be further formed around the first conductive through-via, but as the volume of the metal material filling the inside of the second conductive through-via increases, there could be an issue in that a cell array structure may be cracked.

However, according to the above-described exemplary embodiments, a dummy through-hole 174H may be additionally formed in the process for forming the first through-hole 170H and the second through-hole 172H, and the dummy insulating pillar 174 may be formed by filling the inside of the dummy through hole 174H with an insulating material. Accordingly, it is possible to help reduce or prevent a not-open defect in the process of forming the first through-hole 170H and help reduce or prevent cracks from occurring in the cell array structure CS.

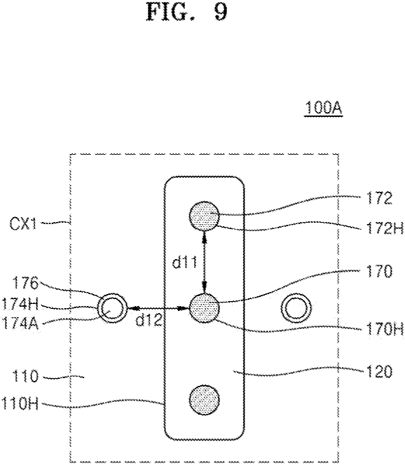

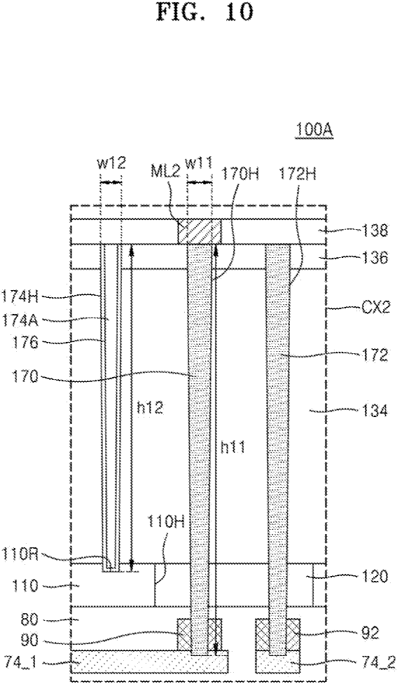

FIG. 9 is a plan view of a semiconductor device 100A according to exemplary embodiments, and FIG. 10 is a cross-sectional view of the semiconductor device 100A of FIG. 9. FIG. 9 is a plan view corresponding to an enlarged plan view of a portion CX1 of FIG. 4, and FIG. 10 is a cross-sectional view corresponding to an enlarged cross-sectional view of a portion CX2 of FIG. 5. In FIGS. 9 and 10, the same reference numerals as in FIGS. 1 to 8 indicate the same components.

Referring to FIGS. 9 and 10, an insulating liner 176 may be further included on the inner wall of the dummy through hole 174H, and the insulating liner 176 may be between the cover insulating layer 134 and the dummy insulating pillar 174A so that the dummy insulating pillar 174A and the cover insulating layer 134 may not directly contact each other. In addition, the insulating liner 176 may be between the dummy insulating pillar 174A and the common source plate 110, so that the dummy insulating pillar 174A may not directly contact the recess portion 110R of the common source plate 110.

In an implementation, the dummy insulating pillar 174A may include silicon oxide, low-k dielectric material, or the like, and the insulating liner 176 may include silicon nitride, silicon oxynitride, or silicon oxide. In an implementation, the insulating liner 176 may be formed using a material different from that of the dummy insulating pillar 174A.

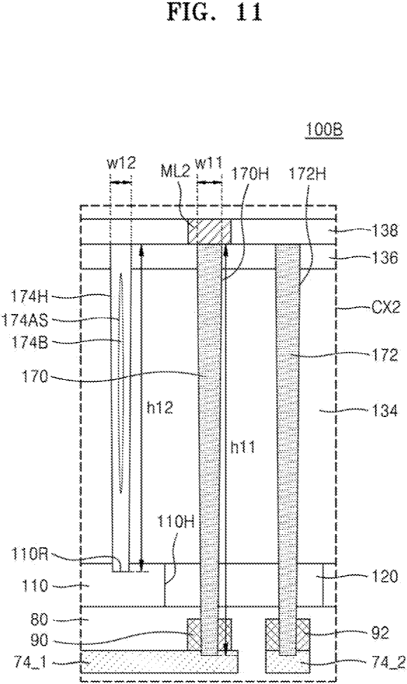

FIG. 11 is a cross-sectional view of a semiconductor device 100B according to exemplary embodiments. FIG. 11 is a cross-sectional view corresponding to an enlarged cross-sectional view of a portion CX2 of FIG. 5. In FIG. 11, the same reference numerals as in FIGS. 1 to 10 denote the same components.

Referring to FIG. 11, the dummy insulating pillar 174B may include a seam 174S therein. In an implementation, in the process of forming the dummy insulating pillar 174B by filling the inside of the dummy through hole 174H with an insulating material, when the insulating material blocks the entrance of the dummy through hole 174H while the inside of the dummy through hole 174H is not completely filled, the seam 174S may be formed, and the seam 174S may be an air space or air gap filled with air or gas.

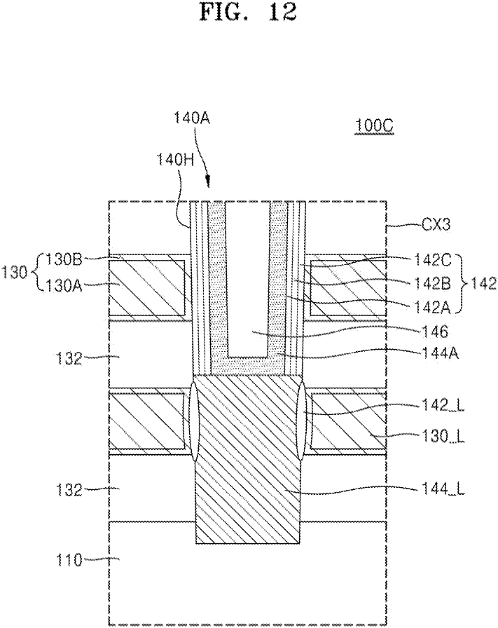

FIG. 12 is a cross-sectional view of a semiconductor device 200 according to exemplary embodiments. FIG. 12 is an enlarged view of a portion corresponding to a portion CX3 of FIG. 5. In FIG. 12, the same reference numerals as in FIGS. 1 to 11 denote the same components.

Referring to FIG. 12, the channel structure 140A may include a gate insulating layer 142, a channel layer 144, a buried insulating layer 146, and a conductive plug 148, and may further include a contact semiconductor layer 144_L and a bottom insulating layer 142_L on or at the bottom of the channel hole 140H. The channel layer 144 may not directly contact the common source plate 110, and may be electrically connected to the common source plate 110 through the contact semiconductor layer 144_L. In an implementation, the contact semiconductor layer 144_L may include a silicon layer formed by a selective epitaxy growth (SEG) process using the common source plate 110 arranged at the bottom of the channel hole 140H as a seed layer.

The bottom insulating layer 142_L may be between the lowermost gate electrode 130_L and the contact semiconductor layer 144_L. In an implementation, the bottom insulating layer 142_L may include silicon oxide and, e.g., may be formed by performing an oxidation process on a portion of a sidewall of the contact semiconductor layer 144_L.

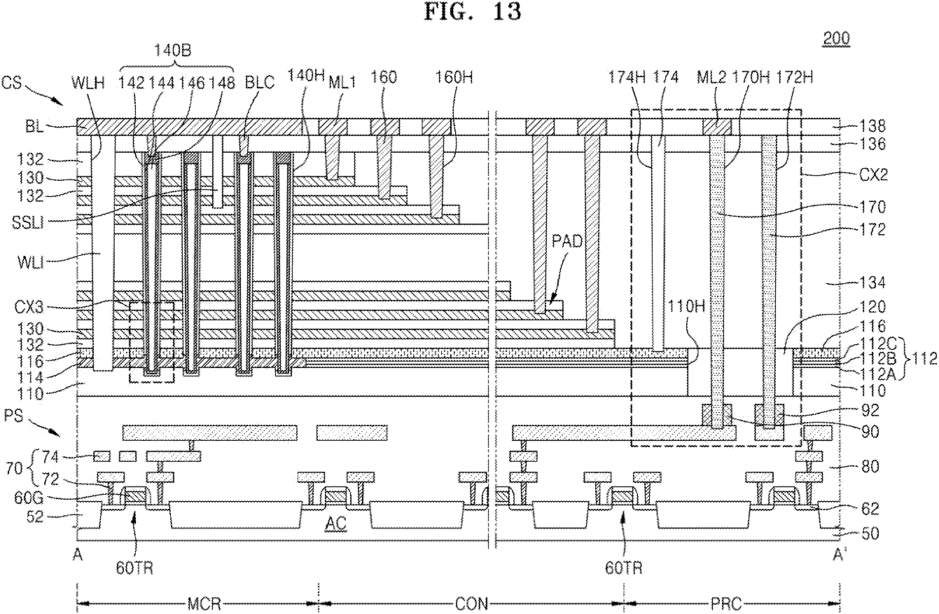

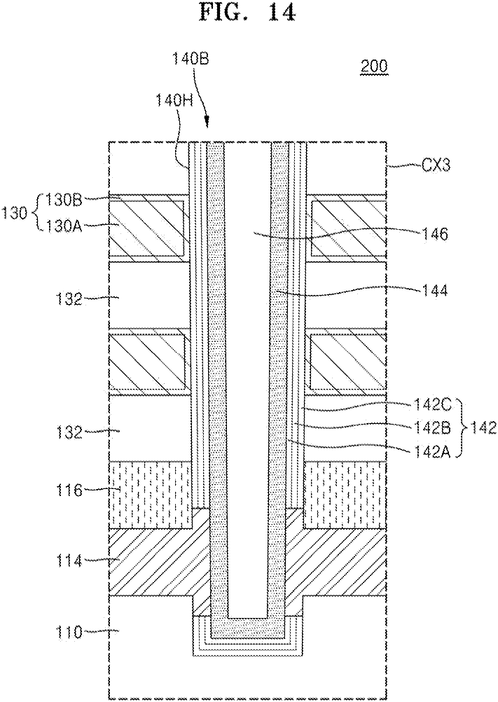

FIG. 13 is a cross-sectional view of a semiconductor device 200 according to exemplary embodiments. FIG. 14 is an enlarged view of a portion CX3 of FIG. 13. In FIGS. 13 and 14, the same reference numerals as in FIGS. 1 to 12 indicate the same components.

Referring to FIGS. 13 and 14, a horizontal semiconductor layer 114 and a support layer 116 may be sequentially stacked on the upper surface of the common source plate 110 in the memory cell region MCR. A lower insulating layer 112 and the support layer 116 may be sequentially stacked on the upper surface of the common source plate 110 in the connection region CON and the peripheral circuit connection region PRC.

In an implementation, the lower insulating layer 112 may include a first insulating layer 112A, a second insulating layer 112B, and a third insulating layer 112C sequentially stacked on the common source plate 110. The first insulating layer 112A and the third insulating layer 112C may include silicon oxide, and the second insulating layer 112B may include silicon nitride.

In an implementation, the horizontal semiconductor layer 114 may include doped polysilicon or undoped polysilicon. The horizontal semiconductor layer 114 may function as a part of a common source region connecting the common source plate 110 and the channel layer 144 to each other. In an implementation, the support layer 116 may include doped or undoped polysilicon. The support layer 116 may serve as a support layer for preventing the mold stack from collapsing or collapsing in a process of removing the sacrificial material layer for forming the horizontal semiconductor layer 114.

The channel structure 140B may include a gate insulating layer 142, a channel layer 144, a buried insulating layer 146, and a conductive plug 148. In an implementation, as shown in FIG. 14, the gate insulating layer 142 may be on an inner wall and a bottom of the channel hole 140H. The bottom surface of the channel layer 144 may be on the gate insulating layer 142 and may not directly contact the common source plate 110, and a bottom sidewall of the channel layer 144 may be surrounded by the horizontal semiconductor layer 114.

The first conductive through-via 170 may extend in the vertical direction Z through the first upper insulating layer 136, the cover insulating layer 134, the insulating plug 120, and the first conductive landing via 90, and the second conductive through-via 172 may extend in the vertical direction Z through the first upper insulating layer 136, the cover insulating layer 134, the insulating plug 120, and the second conductive landing via 92. In an implementation, as shown in the drawing, the dummy insulating pillar 174 may penetrate the first upper insulating layer 136 and the cover insulating layer 134 to contact an upper surface of the supporting layer 116, or may further penetrate the support layer 116 and the lower insulating layer 112 to contact the upper surface of the common source plate 110.

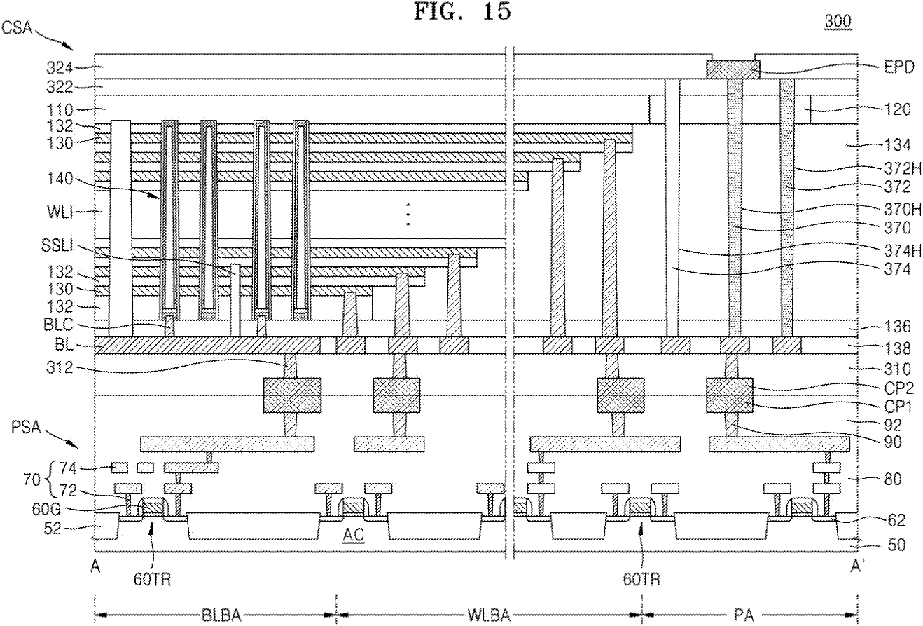

FIG. 15 is a cross-sectional view of a semiconductor device 300 according to exemplary embodiments.

Referring to FIG. 15, the semiconductor device 300 may have a chip to chip (C2C) structure. The C2C structure may mean that an upper chip including a cell array structure CSA may be manufactured on the first wafer, and after a lower chip including a peripheral circuit structure PSA is manufactured on a second wafer different from the first wafer, the upper chip and the lower chip may be connected to each other by a bonding method. In an implementation, the bonding method may refer to a method of electrically connecting the bonding metal formed in the uppermost metal layer of the upper chip and the bonding metal formed in the uppermost metal layer of the lower chip to each other. In an implementation, when the bonding metal is formed of copper (Cu), the bonding method may be a Cu-to-Cu bonding method. In an implementation, the bonding metal may be formed of aluminum (Al) or tungsten (W).

Each of the peripheral circuit structure PSA and the cell array structure CSA of the semiconductor device 300 may include an external pad bonding region PA, a word line bonding region WLBA, and a bit line bonding region BLBA.

The peripheral circuit structure PSA may be similar to the peripheral circuit structure PS described with reference to FIGS. 3 to 8. In an implementation, the peripheral circuit structure PSA may include a peripheral circuit transistor 60TR, a peripheral circuit wiring structure 70, an interlayer insulating layer 80, and a first bonding pad CP1 arranged on the substrate 50. The peripheral circuit wiring structure 70 may include a plurality of peripheral circuit contacts 72 and a plurality of peripheral circuit wiring layers 74. In an implementation, the plurality of peripheral circuit wiring layers 74 may include tungsten, copper, aluminum, or a combination thereof. In an implementation, the uppermost peripheral circuit wiring layer 74 among the plurality of peripheral circuit wiring layers 74 may be formed of copper having a relatively low electrical resistivity, and among the plurality of peripheral circuit wiring layers 74, the peripheral circuit wiring layer 74 at a lower level than the uppermost peripheral circuit wiring layer 74 may be formed of tungsten having a relatively high electrical resistivity.

The cell array structure CSA may be similar to the cell array structure CS described with reference to FIGS. 3 to 8. The cell array structure CSA may include a plurality of gate electrodes 130, a plurality of channel structures 140, and a bit line BL sequentially arranged on the common source plate 110, and an interlayer insulating layer 310 and a second bonding pad CP2 may be arranged on the bit line BL. The second bonding pad CP2 may be electrically connected to the bit line BL through the bonding via 312.

The cell array structure CSA and the peripheral circuit structure PSA may be attached to each other so that the second bonding pad CP2 contacts the first bonding pad CP1 and the interlayer insulating layer 310 contacts the interlayer insulating layer 80. Accordingly, the width of the plurality of gate electrodes 130 in the horizontal direction may increase as the distance from the peripheral circuit structure PSA increases.

A first conductive through-via 370, a second conductive through-via 372, and a dummy insulating pillar 374 may be in the external pad bonding region PA.

The first conductive through-via 370 may be in the first through-hole 370H penetrating the cover insulating layer 134, and the first conductive through-via 370 may be connected to the external bonding pad EPD. The second conductive through-via 372 may be in the second through-hole 372H penetrating the cover insulating layer 134, and may be grounded or floated. The first conductive through-via 370 and the second conductive through-via 372 may be formed of a metal, a metal compound, or a conductive material such as polysilicon.

The dummy insulating pillar 374 may be in the dummy through hole 374H penetrating the cover insulating layer 134, and may include an insulating material such as silicon oxide, silicon nitride, silicon oxynitride, or the like. The second through-hole 372H and the dummy through-hole 374H may function as a dummy through-hole for preventing a not-open defect in an etching process for forming the first through-hole 370H.

An upper insulating layer 322 may be on the upper surface of the common source plate 110, and a passivation layer 324 may be on the upper insulating layer 322 to cover a portion of an upper surface of the external bonding pad EPD.

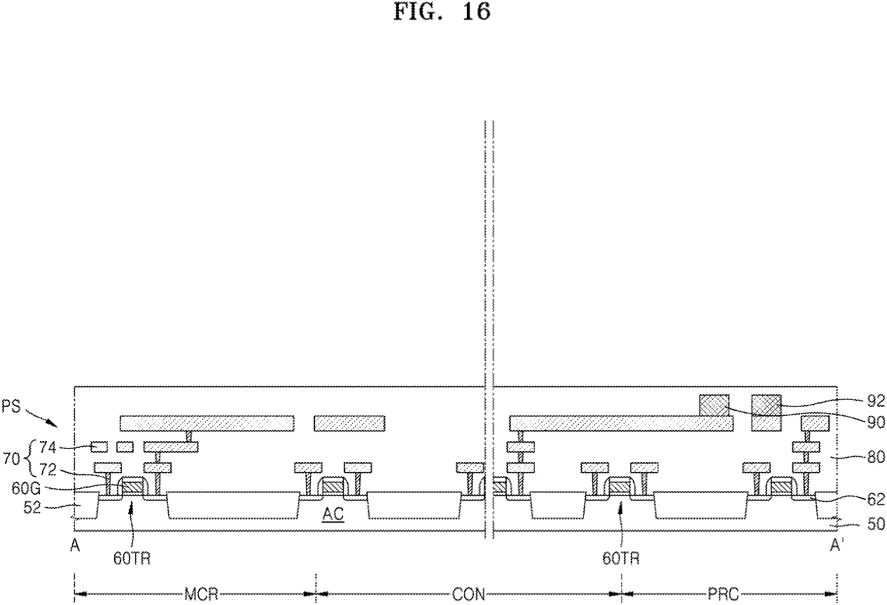

FIGS. 16 to 32 are cross-sectional views of stages in a method of manufacturing the semiconductor device 100 according to exemplary embodiments. FIGS. 16 to 32 are cross-sectional views corresponding to the cross-section taken along line A-A′ of FIG. 4.

Referring to FIG. 16, a peripheral circuit structure PS may be formed on the substrate 50. In an implementation, the substrate 50 may be a single crystal silicon substrate. A plurality of peripheral circuit transistors 60T may be formed on the substrate 50, and the peripheral circuit wiring structure 70 electrically connected to the peripheral circuit transistor 60T and the interlayer insulating layer 80 may be formed.

First and second conductive landing vias 90 and 92 may be further formed on the uppermost peripheral circuit wiring layer 74 in the peripheral circuit connection region PRC. In an implementation, the first and second conductive landing vias 90 and 92 may be formed using polysilicon doped with n-type impurities. Upper surfaces of the first and second conductive landing vias 90 and 92 may be covered by the interlayer insulating layer 80.

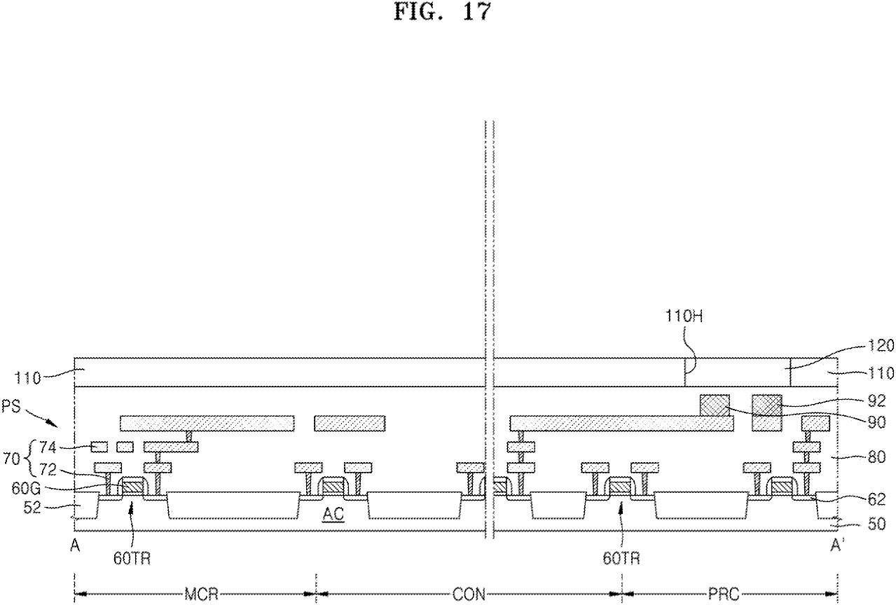

Referring to FIG. 17, a common source plate 110 may be formed on the interlayer insulating layer 80. In an implementation, the common source plate 110 may be formed using a semiconductor doped with an n-type impurity.

Thereafter, a mask pattern may be formed on the common source plate 110, and the opening 110H may be formed by removing a portion of the common source plate 110 using the mask pattern as an etch mask. The opening 110H may be formed in a region that vertically overlaps with at least a portion of the peripheral circuit connection region PRC.

Thereafter, an insulating layer filling the opening 110H may be formed on the common source plate 110, and the insulating plug 120 may be formed by planarizing the upper portion of the insulating layer until the upper surface of the common source plate 110 is exposed.

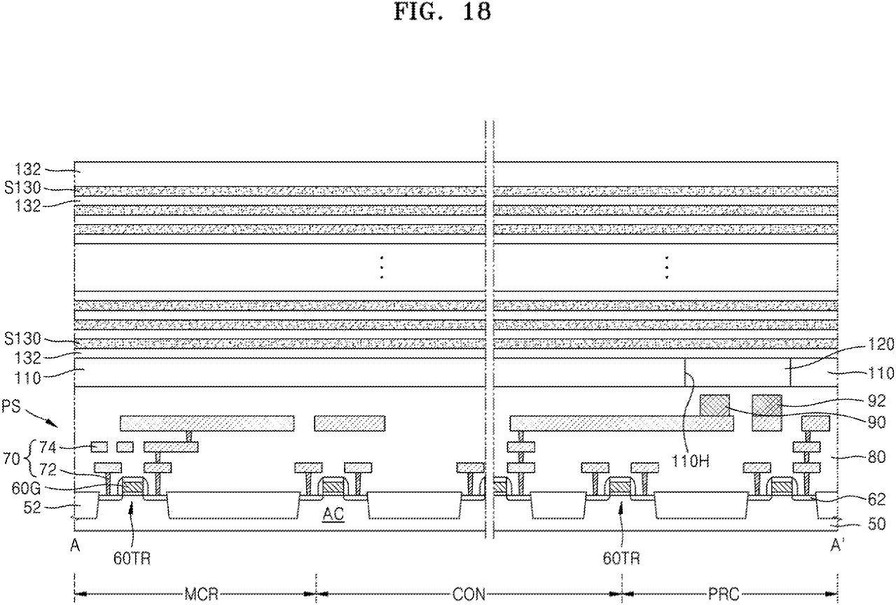

Referring to FIG. 18, a plurality of mold insulating layers 132 and a plurality of sacrificial layers S130 may be alternately formed on the common source plate 110. In an implementation, the plurality of mold insulating layers 132 may include an insulating material such as silicon oxide or silicon oxynitride, and the plurality of sacrificial layers S130 may include silicon nitride, silicon oxynitride, or polysilicon doped with impurities.

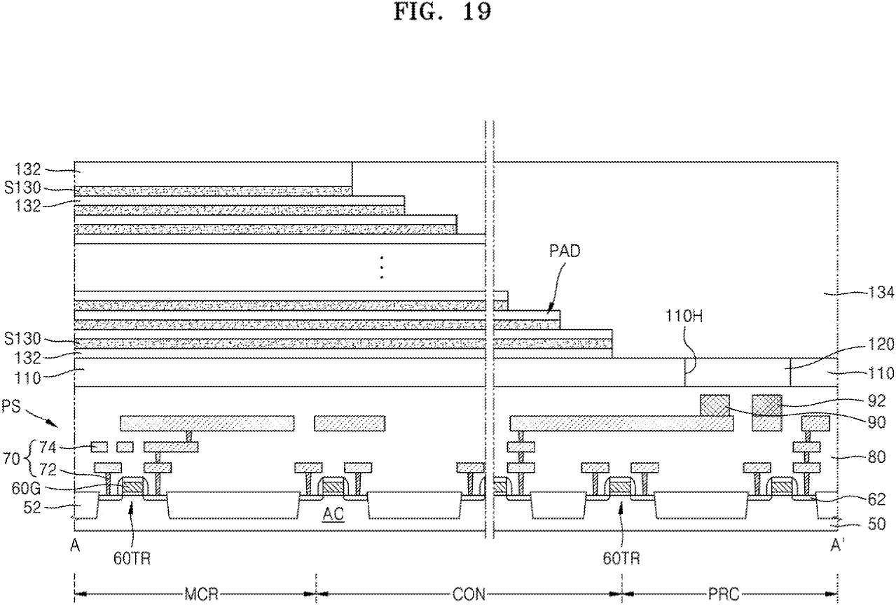

Referring to FIG. 19, the pad portion PAD may be formed by sequentially patterning the plurality of mold insulating layers 132 and the plurality of sacrificial layers S130 on the connection region CON. In an implementation, the pad portion PAD may be formed in a stair shape having a difference in upper surface level along the first horizontal direction (X direction) (refer to FIG. 4).

Thereafter, a cover insulating layer 134 covering the pad portion PAD may be formed. The cover insulating layer 134 may include an insulating material such as silicon oxide or silicon oxynitride.

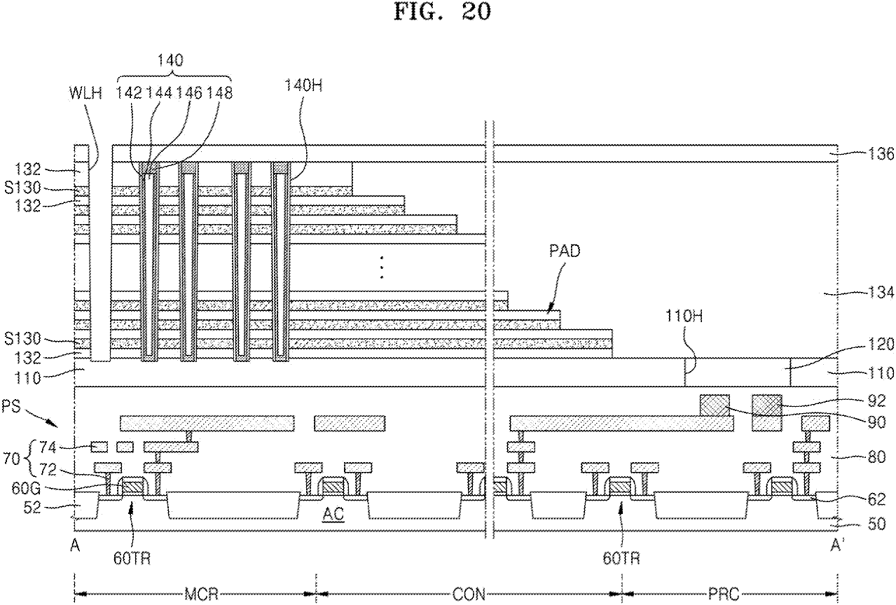

Referring to FIG. 20, a mask pattern may be formed on the uppermost mold insulating layer 132 and the cover insulating layer 134, and channel holes 140H may be formed by patterning the plurality of mold insulating layers 132 and the plurality of sacrificial layers S130 using the mask pattern as an etching mask.

Thereafter, the channel structure 140 including the gate insulating layer 142, the channel layer 144, the buried insulating layer 146, and the conductive plug 148 may be formed on the inner wall of the channel hole 140H.

In an implementation, in the process of forming the channel structure 140, a dummy channel structure penetrating the pad portion PAD in the connection region CON may be formed together.

Thereafter, a first upper insulating layer 136 may be formed on the uppermost mold insulating layer 132 and the cover insulating layer 134. Thereafter, a mask pattern may be formed on the first upper insulating layer 136, and a gate stack separation opening WLH may be formed by removing portions of the plurality of mold insulating layers 132 and the plurality of sacrificial layers S130 using the mask pattern as an etching mask.

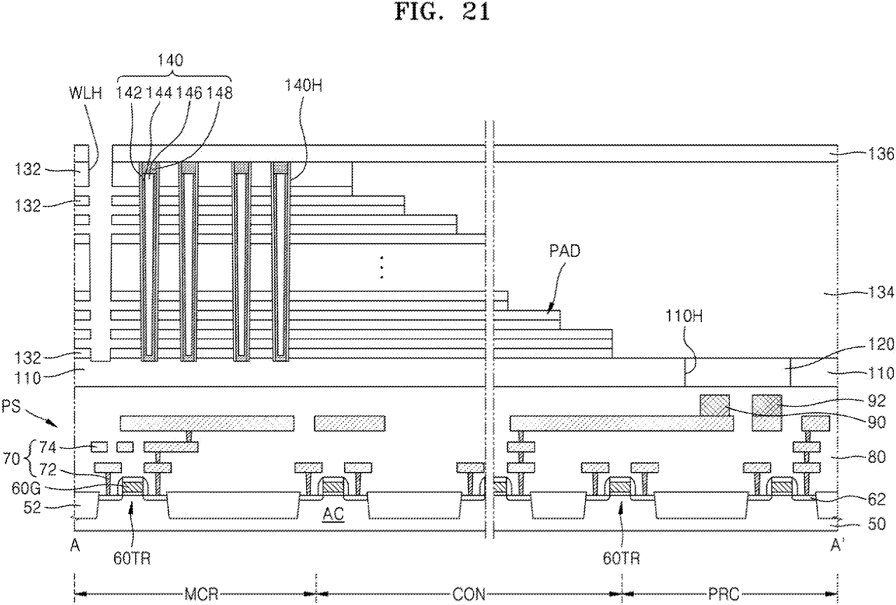

Referring to FIG. 21, the plurality of sacrificial layers S130 exposed on the sidewall of the gate stack separation opening WLH may be removed. In an implementation, the removal process of the plurality of sacrificial layers S130 may be a wet etching process using a phosphoric acid solution as an etchant. As the plurality of sacrificial layers S130 are removed, a portion of the sidewall of the channel structure 140 may be exposed.

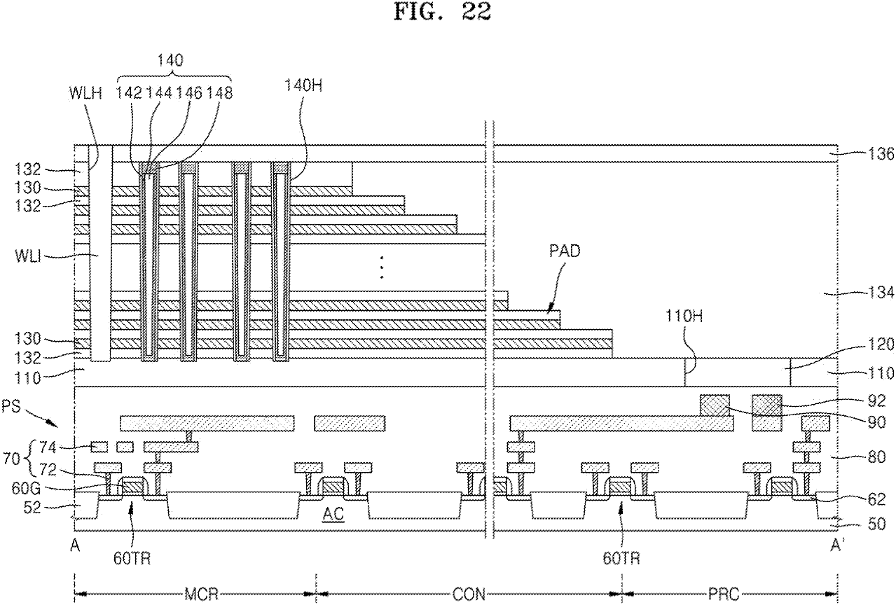

Referring to FIG. 22, a plurality of gate electrodes 130 may be formed by filling a conductive material at a location where the plurality of sacrificial layers S130 are removed.

Thereafter, an insulating material may be filled in the gate stack separation opening WLH to form a gate stack separation insulating layer WLI.

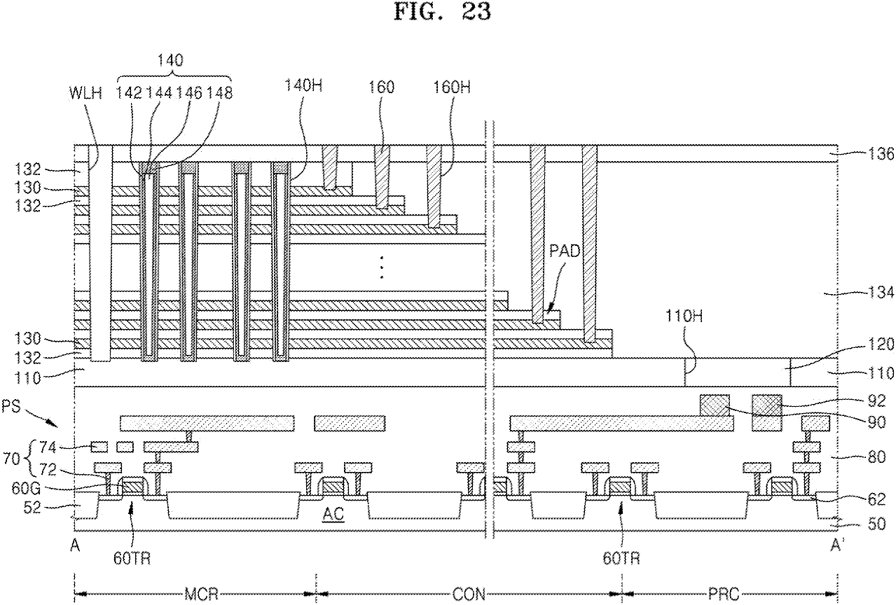

Referring to FIG. 23, a cell contact hole 160H penetrating the first upper insulating layer 136 and the cover insulating layer 134 may be formed. Thereafter, a conductive material may be filled in the cell contact hole 160H to form the cell contact plug 160 electrically connected to the pad portion PAD.

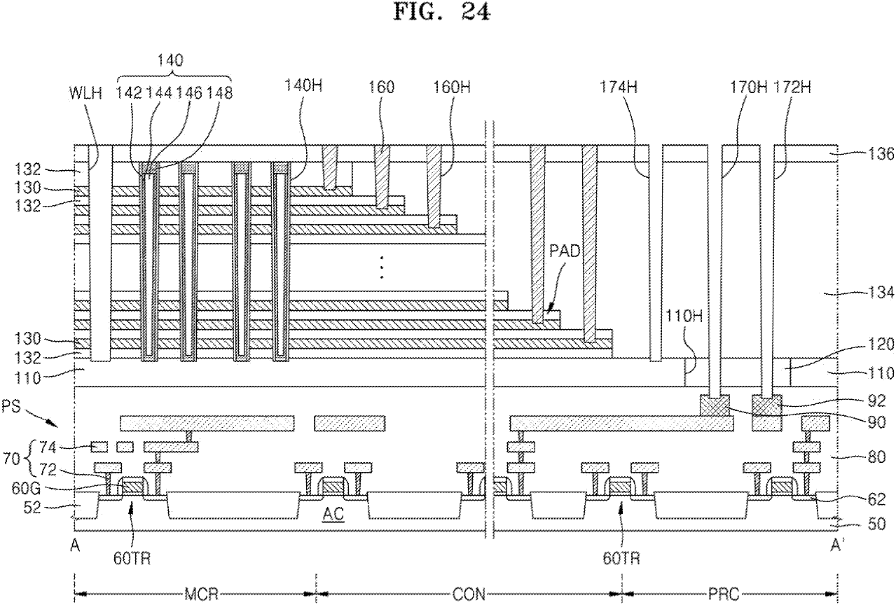

Referring to FIG. 24, a mask pattern may be formed to cover the memory cell region MCR and the connection region CON and to expose portions of an upper surface of the first upper insulating layer 136 on the peripheral circuit connection region PRC. Thereafter, using the mask pattern as an etching mask, a first through hole 170H and a second through hole 172H penetrating the first upper insulating layer 136, the cover insulating layer 134, and the insulating plug 120 may be formed and a dummy through hole 174H penetrating the first upper insulating layer 136 and the cover insulating layer 134 may be formed.

In an implementation, the first through-hole 170H and the second through-hole 172H may be formed at a position that vertically overlaps with the insulating plug 120, and the dummy through hole 174H may be formed at a position that vertically overlaps with the common source plate 110.

In an implementation, the first through-hole 170H, the second through-hole 172H, and the dummy through-hole 174H may be formed using the same etching process, and the etching process may be performed using, e.g., an etching condition having a relatively low etching rate for polysilicon and a relatively high etching rate for silicon oxide. In the etching process, the upper surface of the common source plate 110 may be exposed at the bottom of the dummy through hole 174H, and the first through-hole 170H and the second through-hole 172H may penetrate the insulating plug 120 and further extend into a portion of the interlayer insulating layer 80, and expose upper surfaces of the first and second conductive landing vias 90 and 92.

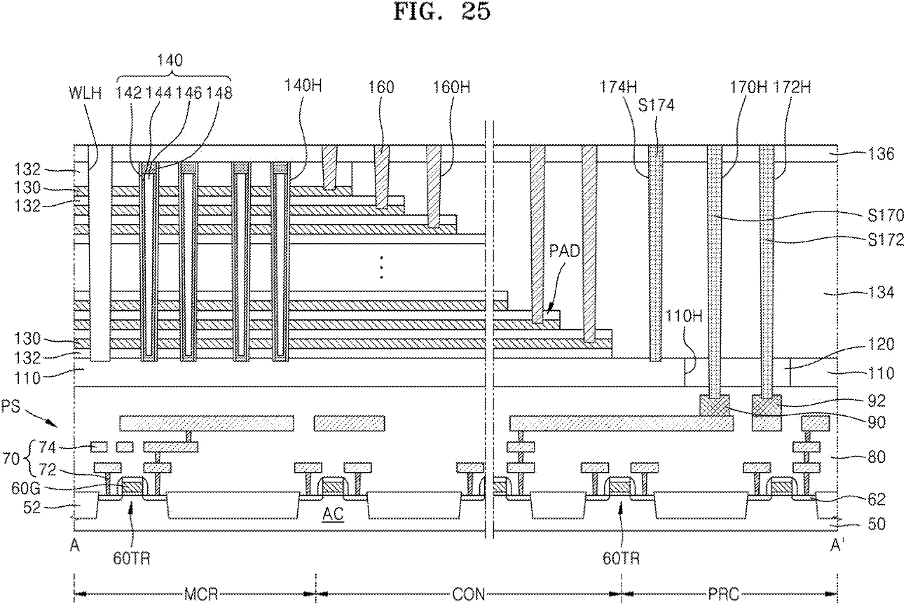

Referring to FIG. 25, a first sacrificial buried layer S170, a second sacrificial buried layer S172, and a dummy sacrificial buried layer S174 may be formed in the first through-hole 170H, the second through-hole 172H, and the dummy through-hole 174H. In an implementation, the first sacrificial buried layer S170, the second sacrificial buried layer S172, and the dummy sacrificial buried layer S174 may be formed using polysilicon.

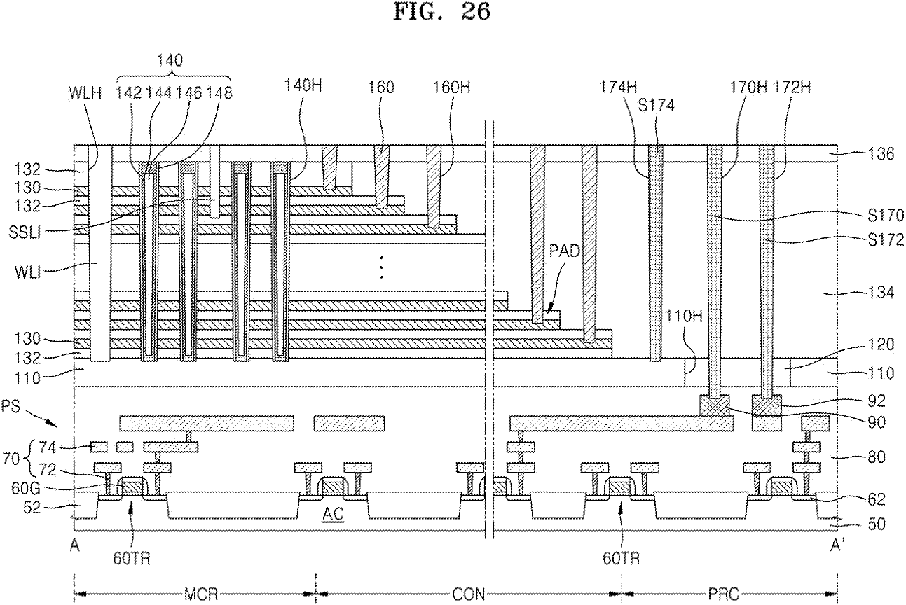

Referring to FIG. 26, the string separation opening SSLH (refer to FIG. 4) may be formed by removing the first upper insulating layer 136, the uppermost two gate electrodes 130, and the uppermost two mold insulating layers 132 in the memory cell region MCR, and a string separation insulating layer SSLI filling in the string separation opening SSLH may be formed.

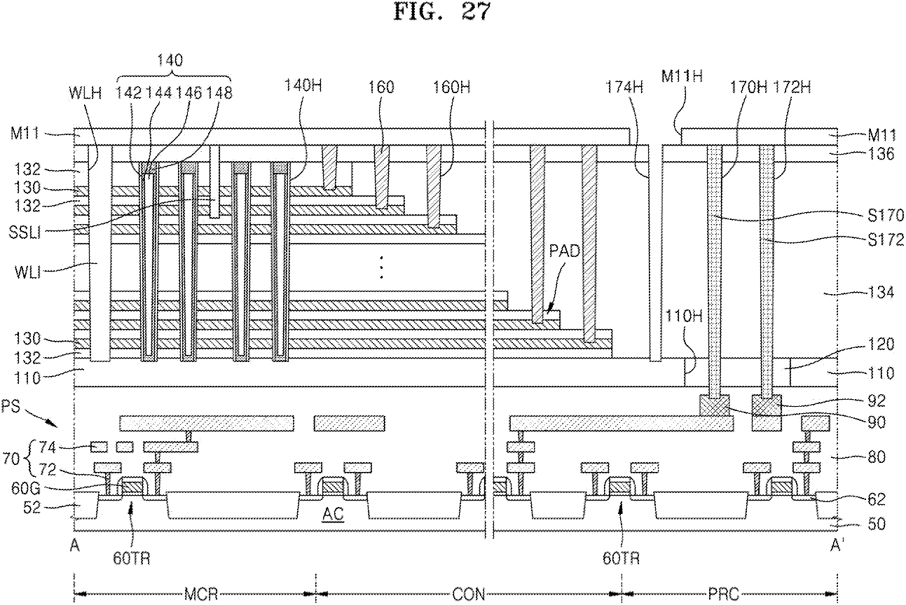

Referring to FIG. 27, a first mask pattern M11 covering the first sacrificial buried layer S170 and the second sacrificial buried layer S172 may be formed on the first upper insulating layer 136. The first mask pattern M11 may have a first opening M11H, and may expose an upper surface of the dummy sacrificial buried layer S174 and the dummy through hole 174H in the peripheral circuit connection region PRC.

Thereafter, the dummy sacrificial buried layer S174 may be removed and the inner wall of the dummy through hole 174H may be exposed again.

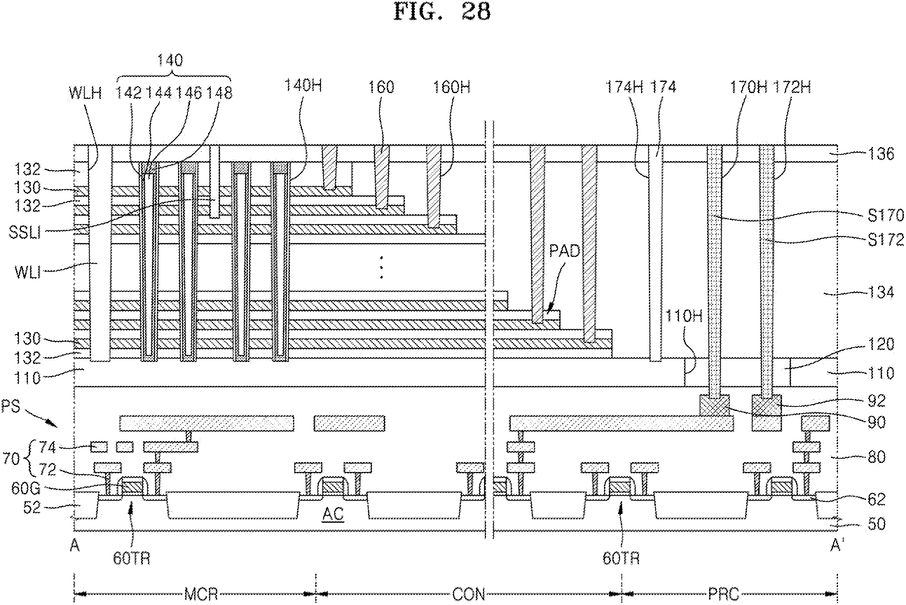

Referring to FIG. 28, the dummy insulating pillar 174 may be formed in the dummy through hole 174H by using an insulating material. In an implementation, the dummy insulating pillar 174 may be formed of a material layer that continuously fills the inside of the dummy through hole 174H using silicon oxide.

In an implementation, in the process of forming the dummy insulating pillar 174, the insulating liner 176 may be first formed on the inner wall of the dummy through hole 174H, and then the dummy insulating pillar 174A may be formed inside the dummy through hole 174H. In an implementation, the insulating liner 176 may be formed using a different material than the dummy insulating pillar 174A. In this case, the semiconductor device 100A described with reference to FIGS. 9 and 10 may be formed.

In an implementation, in the process of forming the dummy insulating pillar 174, when the insulating material blocks the entrance of the dummy through hole 174H while the inside of the dummy through hole 174H is not completely filled, a seam 174AS may be formed inside the dummy insulating pillar 174B. In this case, the semiconductor device 100B described with reference to FIG. 11 may be formed.

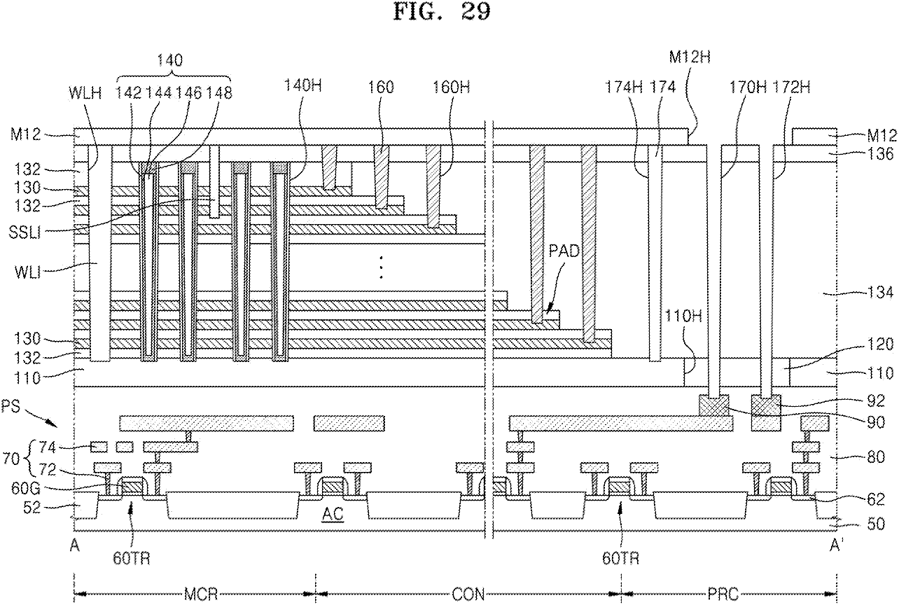

Referring to FIG. 29, a second mask pattern M12 covering the dummy insulating pillar 174 may be formed on the first upper insulating layer 136. The second mask pattern M12 may have a second opening M12H, and may expose upper surfaces of the first sacrificial buried layer S170 and the second sacrificial buried layer S172 on the peripheral circuit connection region PRC.

Thereafter, the first sacrificial buried layer S170 and the second sacrificial buried layer S172 may be removed, and inner walls of the first and second through holes 170H and 172H may be exposed again.

By removing the first sacrificial buried layer S170 and the second sacrificial buried layer S172, the upper surfaces of the first and second conductive landing vias 90 and 92 are exposed at the bottom of the first through hole 170H and the second through hole 172H, respectively.

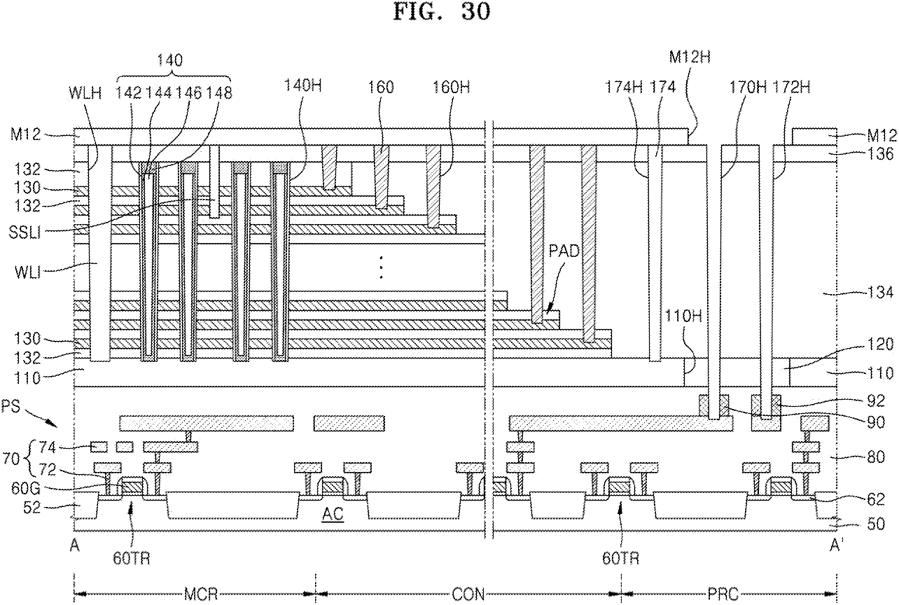

Referring to FIG. 30, an etch-back process may be performed on the bottom of the first through-hole 170H and the second through-hole 172H such that the first through-hole 170H and the second through-hole 172H may be further expanded in the vertical direction. The first through-hole 170H and the second through-hole 172H may penetrate the first and second conductive landing vias 90 and 92, respectively, and an upper surface of the uppermost peripheral circuit wiring layer 74 may be exposed at the bottom of the first through hole 170H and the second through hole 172H.

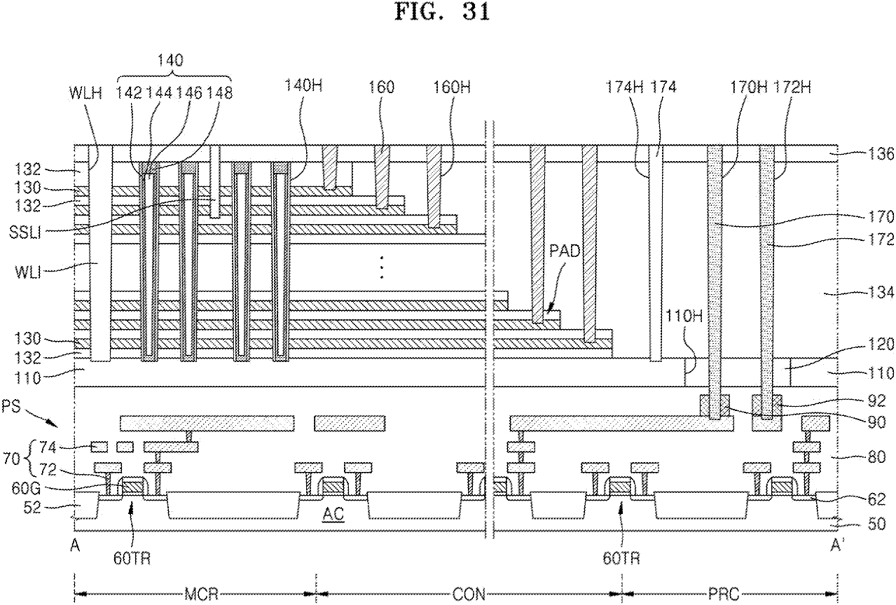

In an implementation, as illustrated in FIG. 30, the bottoms of the first through-hole 170H and the second through-hole 172H may extend in the vertical direction, such that the first through-hole 170H and the second through-hole 172H penetrate the first and second conductive landing vias 90 and 92, or the process of expanding the bottom in the vertical direction may be omitted. In this case, the first and second conductive through-vias 170 and 172 (refer to FIG. 31) respectively formed inside the first through-hole 170H and the second through-hole 172H may contact the upper surfaces of the first and second conductive landing vias 90 and 92, respectively, and may not contact the upper surface of the uppermost peripheral circuit wiring layer 74.

Referring to FIG. 31, a conductive layer filling the inside of the first through hole 170H and the second through hole 172H may be formed, and the upper portion of the conductive layer may be planarized until an upper surface of the first upper insulating layer 136 is exposed, such that a first conductive through-via 170 and a second conductive through-via 172 may be formed in the first through-hole 170H and the second through-hole 172H, respectively.

In an implementation, the first and second conductive through-vias 170 and 172 may be formed using tungsten, titanium, tantalum, copper, aluminum, titanium nitride, tantalum nitride, tungsten nitride, or a combination thereof.

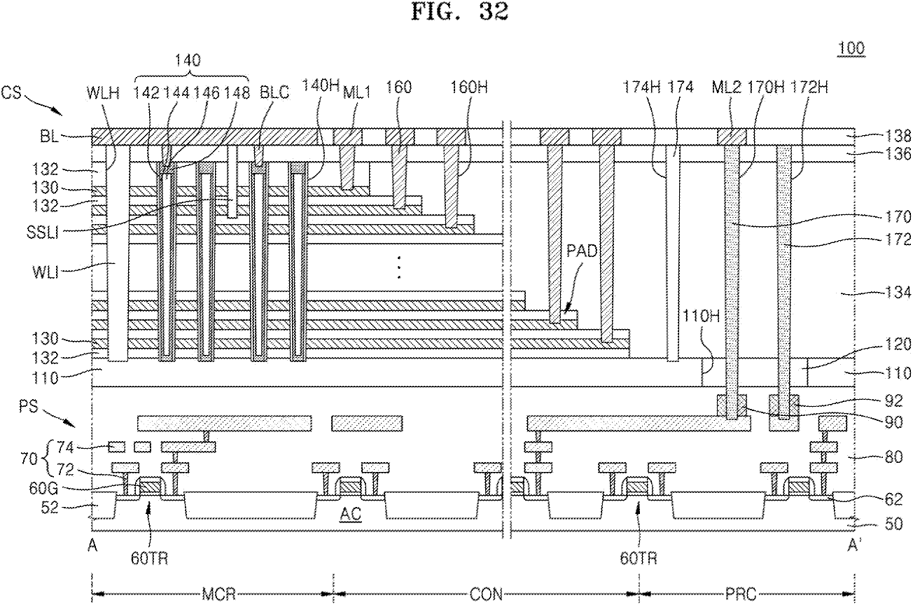

Referring to FIG. 32, a bit line contact BLC electrically connected to the channel structure 140 may be formed through the first upper insulating layer 136.

Thereafter, a bit line BL electrically connected to the bit line contact BLC may be formed on the memory cell region MCR, a first wiring line ML1 electrically connected to the cell contact plug 160 may be formed on the connection region CON, and a second wiring line ML2 electrically connected to the first conductive through-via 170 may be formed on the peripheral circuit connection region PRC. Thereafter, a second upper insulating layer 138 surrounding the sidewalls of the bit line BL, the first wiring line ML1, and the second wiring line ML2 may be formed on the first upper insulating layer 136.

The semiconductor device 100 may be completed by performing the above-described processes.

In some devices, first conductive through-vias on the peripheral circuit connection region may be formed in a relatively small number, or may have a relatively large separation distance from the adjacent first conductive through-via. In this case, in the etching process for forming the first through-hole, the etching depth of the first through-hole may be smaller than the target depth, and a not-open defect in which the upper surface of the first conductive landing via is not exposed could occur. In order to help prevent this, a second conductive through-via serving as a dummy through-via may be further formed around the first conductive through-via, but as the volume of the metal material filling the inside of the second conductive through-via increases, there is a problem in that the cell array structure CS could be cracked.

According to the above-described exemplary embodiments, a dummy through-hole 174H may be additionally formed in the process for forming the first through-hole 170H and the second through-hole 172H, and the dummy insulating pillar 174 may be formed by filling the inside of the dummy through hole 174H with an insulating material. Accordingly, it is possible to help prevent a not-open defect in the process of forming the first through-hole 170H and help prevent cracks from occurring in the cell array structure CS.

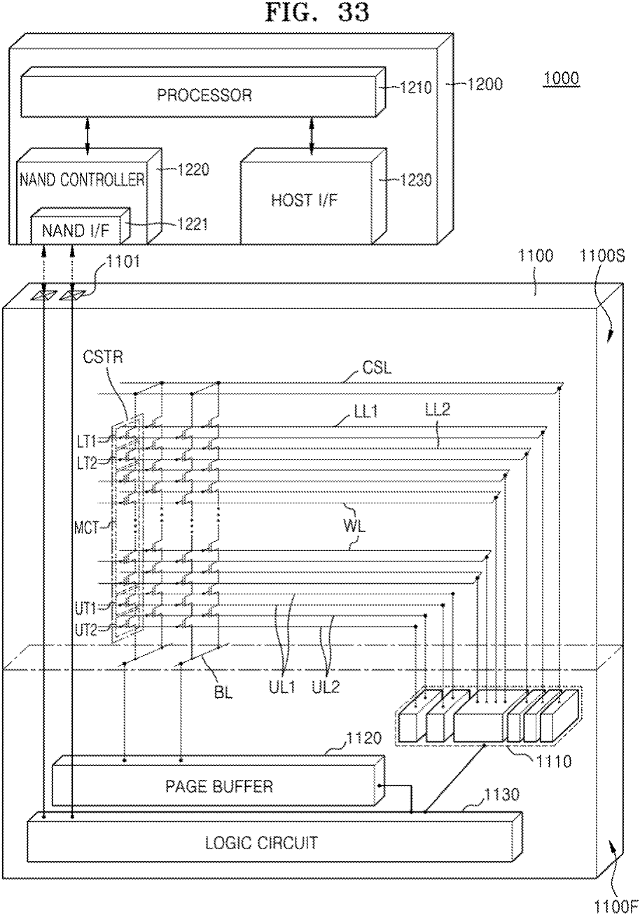

FIG. 33 is a diagram schematically illustrating a data storage system 1000 including a semiconductor device according to exemplary embodiments.

Referring to FIG. 33, the data storage system 1000 may include one or more semiconductor devices 1100 and a memory controller 1200 electrically connected to the semiconductor device 1100. The data storage system 1000 may be, e.g., a solid state drive (SSD) device including at least one semiconductor device 1100, a universal serial bus (USB), a computing system, a medical device, or a communication device.

The semiconductor device 1100 may be a non-volatile semiconductor device, e.g., the semiconductor device 1100 may be a NAND flash semiconductor device including one of the semiconductor devices 10, 100, 100A, 100B, 100C, 200, and 300 described with reference to FIGS. 1 to 15. The semiconductor device 1100 may include a first structure 1100F and a second structure 1100S on the first structure 1100F. The first structure 1100F may be a peripheral circuit structure including a row decoder 1110, a page buffer 1120, and a logic circuit 1130.

The second structure 1100S may be a memory cell structure including a bit line BL, a common source line CSL, a plurality of word lines WL, first and second string select lines UL1 and UL2, first and second ground select lines LL1 and LL2, and a plurality of memory cell strings CSTR between the bit line BL and the common source line CSL.

In the second structure 1100S, each of the plurality of memory cell strings CSTR may include ground select transistors LT1 and LT2 adjacent to the common source line CSL, string select transistors UT1 and UT2 adjacent to the bit line BL, and a plurality of memory cell transistors MCT between the ground select transistors LT1 and LT2 and the string select transistors UT1 and UT2. The number of ground select transistors LT1 and LT2 and the number of string select transistors UT1 and UT2 may be variously modified according to embodiments.

In an implementation, the plurality of ground select lines LL1 and LL2 may be connected to gate electrodes of the ground select transistors LT1 and LT2, respectively. The word line WL may be connected to a gate electrode of the memory cell transistor MCT. The plurality of string select lines UL1 and UL2 may be respectively connected to gate electrodes of the string select transistors UT1 and UT2.

The common source line CSL, the plurality of ground select lines LL1 and LL2, the plurality of word lines WL, and the plurality of string select lines UL1 and UL2 may be connected to the row decoder 1110. The plurality of bit lines BL may be electrically connected to the page buffer 1120.

The semiconductor device 1100 may communicate with the memory controller 1200 through the input/output pad 1101 electrically connected to the logic circuit 1130. The input/output pad 1101 may be electrically connected to the logic circuit 1130.

The memory controller 1200 may include a processor 1210, a NAND controller 1220, and a host interface 1230. In an implementation, the data storage system 1000 may include a plurality of semiconductor devices 1100, and in this case, the memory controller 1200 may control the plurality of semiconductor devices 1100.

The processor 1210 may control the overall operation of the data storage system 1000 including the memory controller 1200. The processor 1210 may operate according to a predetermined firmware, and may access the semiconductor device 1100 by controlling the NAND controller 1220. The NAND controller 1220 may include a NAND interface 1221 that handles communication with the semiconductor device 1100. Through the NAND interface 1221, a control command for controlling the semiconductor device 1100, data to be written to the plurality of memory cell transistors MCT of the semiconductor device 1100, and data to be read from the plurality of memory cell transistors MCT of the semiconductor device 1100 may be transmitted. The host interface 1230 may provide a communication function between the data storage system 1000 and an external host. When receiving a control command from an external host through the host interface 1230, the processor 1210 may control the semiconductor device 1100 in response to the control command.

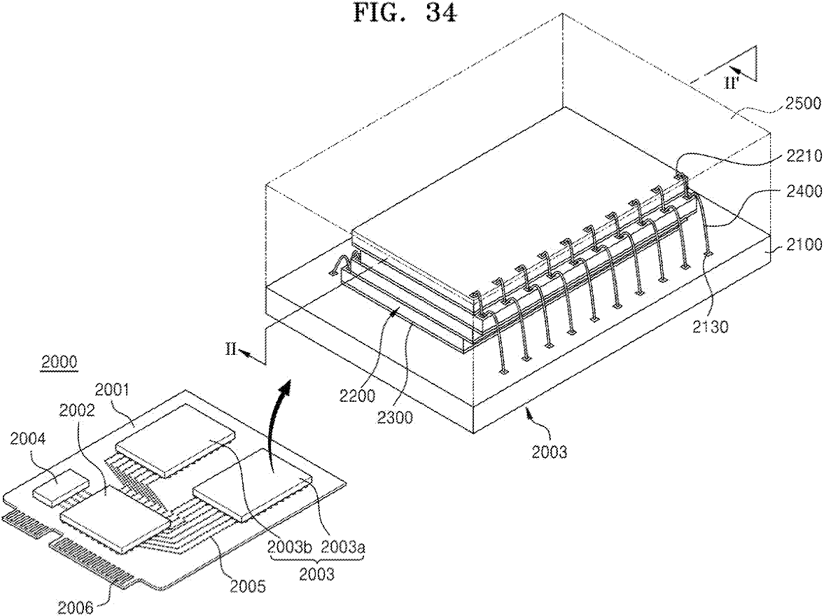

FIG. 34 is a perspective view schematically illustrating a data storage system 2000 including a semiconductor device according to exemplary embodiments.

Referring to FIG. 34, a data storage system 2000 according to an exemplary embodiment may include a main board 2001, a memory controller 2002 mounted on the main board 2001, one or more semiconductor packages 2003, and a DRAM 2004. The semiconductor package 2003 and the DRAM 2004 may be connected to the memory controller 2002 by a plurality of wiring patterns 2005 formed on the main board 2001.

The main board 2001 may include a connector 2006 including a plurality of pins coupled to an external host. The number and arrangement of the plurality of pins in the connector 2006 may vary according to a communication interface between the data storage system 2000 and the external host. In an implementation, the data storage system 2000 may communicate with an external host according to any one of the interfaces such as Universal Serial Bus (USB), Peripheral Component Interconnect Express (PCI-Express), Serial Advanced Technology Attachment (SATA), and M-Phy for Universal Flash Storage (UFS). In an implementation, the data storage system 2000 may operate by power supplied from an external host through the connector 2006. The data storage system 2000 may further include a power management integrated circuit (PMIC) for distributing power supplied from the external host to the memory controller 2002 and the semiconductor package 2003.

The memory controller 2002 may write data to or read data from the semiconductor package 2003, and may help improve the operating speed of the data storage system 2000.

The DRAM 2004 may be a buffer memory for reducing a speed difference between the semiconductor package 2003, that is, a data storage space, and an external host. The DRAM 2004 included in the data storage system 2000 may operate as a kind of cache memory, and may provide a space for temporarily storing data in a control operation for the semiconductor package 2003. When the data storage system 2000 includes the DRAM 2004, the memory controller 2002 may further include a DRAM controller for controlling the DRAM 2004 in addition to the NAND controller for controlling the semiconductor package 2003.

The semiconductor package 2003 may include first and second semiconductor packages 2003a and 2003b spaced apart from each other. Each of the first and second semiconductor packages 2003a and 2003b may be a semiconductor package including a plurality of semiconductor chips 2200. Each of the first and second semiconductor packages 2003a and 2003b may include a package substrate 2100, a plurality of semiconductor chips 2200 on the package substrate 2100, an adhesive layer 2300 arranged on a lower surface of each of the plurality of semiconductor chips 2200, a connection structure 2400 electrically connecting the plurality of semiconductor chips 2200 and the package substrate 2100, and a molding layer 2500 covering the plurality of semiconductor chips 2200 and the connection structure 2400 on the package substrate 2100.

The package substrate 2100 may be a printed circuit board including a plurality of package upper pads 2130. Each of the plurality of semiconductor chips 2200 may include an input/output pad 2210. The input/output pad 2210 may correspond to the input/output pad 1101 of FIG. 33. Each of the plurality of semiconductor chips 2200 may include at least one of the semiconductor devices 10, 100, 100A, 100B, 100C, 200, and 300 described with reference to FIGS. 1 to 15.

In an implementation, the connection structure 2400 may be a bonding wire electrically connecting the input/output pad 2210 and the package upper pad 2130. Accordingly, in the first and second semiconductor packages 2003a and 2003b, the plurality of semiconductor chips 2200 may be electrically connected to each other by a bonding wire method, and may be electrically connected to the package upper pad 2130 of the package substrate 2100. In an implementation, in relation to the first and second semiconductor packages 2003a and 2003b, the plurality of semiconductor chips 2200 may be electrically connected to each other by a connection structure including a through silicon via (TSV) instead of the bonding wire type connection structure 2400.

In an implementation, the memory controller 2002 and the plurality of semiconductor chips 2200 may be included in one package. In an implementation, the memory controller 2002 and the plurality of semiconductor chips 2200 may be mounted on a separate interposer board different from the main board 2001, and the memory controller 2002 and the plurality of semiconductor chips 2200 may be connected to each other by wiring formed on the interposer substrate.

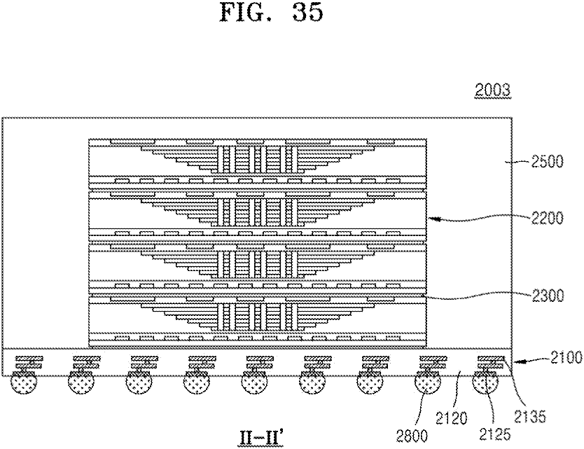

FIG. 35 is a cross-sectional view schematically illustrating semiconductor packages 2003 according to exemplary embodiments. FIG. 35 is a cross-sectional view taken along line II-II′ of FIG. 34.

Referring to FIG. 35, in the semiconductor package 2003, the package substrate 2100 may be a printed circuit board. The package substrate 2100 may include a package substrate body part 2120, a plurality of package upper pads 2130 (refer to FIG. 16) on an upper surface of the package substrate body part 2120, a plurality of lower pads 2125 on or exposed through a lower surface of the package substrate body part 2120, and a plurality of internal wirings 2135 that electrically connect the plurality of package upper pads 2130 (refer to FIG. 16) and the plurality of lower pads 2125 in the package substrate body part 2120. As shown in FIG. 35, the plurality of package upper pads 2130 may be electrically connected to the plurality of connection structures 2400. As shown in FIG. 35, the plurality of lower pads 2125 may be connected to the plurality of wiring patterns 2005 on the main board 2001 of the data storage system 2000 shown in FIG. 34 through the plurality of conductive bumps 2800. Each of the plurality of semiconductor chips 2200 may include at least one of the semiconductor devices 10, 100, 100A, 100B, 100C, 200, and 300 described with reference to FIGS. 1 to 15.

By way of summation and review, to help increase the data storage capacity of a semiconductor device, a semiconductor device including memory cells arranged three-dimensionally instead of memory cells arranged two-dimensionally has been considered.

One or more embodiments may provide a semiconductor device having a vertical channel.

One or more embodiments may provide a semiconductor device capable of preventing defects in a through-via forming process.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A semiconductor device, comprising:
a substrate including a first region, a second region, and a third region;
a peripheral circuit structure on the substrate and including a peripheral circuit and a plurality of wiring layers connected to the peripheral circuit;
a common source plate on the peripheral circuit structure and extending in a horizontal direction;
gate electrodes on the common source plate on the first region and the second region, spaced apart from each other in a first direction perpendicular to an upper surface of the substrate, the gate electrodes having a stair shape on the second region;
a channel structure extending in the first direction through the gate electrodes on the first region;
a first conductive through-via penetrating the common source plate on the third region and electrically connected to the plurality of wiring layers; and
a dummy insulating pillar adjacent to the first conductive through-via on the third region and connected to an upper surface of the common source plate.

2. The semiconductor device as claimed in claim 1, further comprising:
a cover insulating layer on the second region and the third region, the cover insulating layer covering the gate electrodes having a stair shape on the second region; and
an insulating plug in an opening penetrating the common source plate,
wherein the first conductive through-via is in a first through-hole penetrating the cover insulating layer and the insulating plug, and
wherein the dummy insulating pillar is in a dummy through hole penetrating the cover insulating layer.

3. The semiconductor device as claimed in claim 2, further comprising a second conductive through-via adjacent to the first conductive through-via and in a second through-hole penetrating the cover insulating layer and the insulating plug.

4. The semiconductor device as claimed in claim 3, further comprising:
a first conductive landing via surrounding a bottom sidewall of the first conductive through-via and on a first wiring layer of the plurality of wiring layers; and
a second conductive landing via surrounding a bottom sidewall of the second conductive through-via and on a second wiring layer of the plurality of wiring layers,
wherein the first conductive landing via is connected to the peripheral circuit through the first wiring layer, and
wherein the second conductive landing via and the second wiring layer are floated or grounded.

5. The semiconductor device as claimed in claim 2, wherein:
the dummy through hole has a bottom recessed from an upper surface of the common source plate, and
the dummy insulating pillar fills the bottom of the dummy through hole.

6. The semiconductor device as claimed in claim 5, wherein a bottom surface of the dummy insulating pillar is at a level lower than the upper surface of the common source plate.

7. The semiconductor device as claimed in claim 5, wherein:
the dummy insulating pillar is a continuous material layer filling an inside of the dummy through hole, and
a bottom surface of the dummy insulating pillar is in direct contact with the upper surface of the common source plate.

8. The semiconductor device as claimed in claim 5, further comprising an insulating liner conformally on an inner wall of the dummy through hole and between the dummy insulating pillar and the cover insulating layer.

9. The semiconductor device as claimed in claim 5, further comprising a seam extending in the first direction within the dummy insulating pillar.

10. The semiconductor device as claimed in claim 1, wherein:
the first conductive through-via has a first height in the first direction,
the dummy insulating pillar has a second height in the first direction, and
the second height is greater than or equal to 90 % of the first height and less than 100 % of the first height.

11. The semiconductor device as claimed in claim 1, wherein:
the first conductive through-via has a first width at an upper surface of the first conductive through-via in a second direction parallel to the upper surface of the substrate,
the dummy insulating pillar has a second width in the second direction at an upper surface of the dummy insulating pillar, and
the second width is greater than or equal to 90 % of the first width and less than 100 % of the first width.

12. A semiconductor device, comprising:
a substrate including a first region, a second region, and a third region;
a peripheral circuit structure on the substrate, the peripheral circuit structure including a peripheral circuit and a plurality of wiring layers connected to the peripheral circuit;
a common source plate on the peripheral circuit structure, extending in a horizontal direction, and including an opening on the third region;
an insulating plug filling an inside of the opening of the common source plate;
gate electrodes on the common source plate on the first region and the second region, spaced apart from each other in a first direction perpendicular to an upper surface of the substrate, and having a stair shape on the second region;
a cover insulating layer on the second region and the third region, the cover insulating layer covering portions of the gate electrodes having a stair shape on the second region;
a first conductive through-via in a first through-hole penetrating the cover insulating layer and the insulating plug on the third region and electrically connected to the plurality of wiring layers;
a second conductive through-via adjacent to the first conductive through-via on the third region and in a second through-hole penetrating the cover insulating layer and the insulating plug; and
a dummy insulating pillar adjacent to the first conductive through-via on the third region, in a dummy through hole penetrating the cover insulating layer, and having a bottom on an upper surface of the common source plate.

13. The semiconductor device as claimed in claim 12, wherein a bottom surface of the first conductive through-via is at a lower level than a bottom surface of the dummy insulating pillar.

14. The semiconductor device as claimed in claim 12, further comprising:
a first conductive landing via surrounding a bottom sidewall of the first conductive through-via and on a first wiring layer of the plurality of wiring layers; and
a second conductive landing via surrounding a bottom sidewall of the second conductive through-via and on a second wiring layer of the plurality of wiring layers.

15. The semiconductor device as claimed in claim 14, wherein:
the first conductive landing via is connected to the peripheral circuit through the first wiring layer, and
the second conductive landing via and the second wiring layer are floated or grounded.

16. The semiconductor device as claimed in claim 14, wherein:
the first conductive landing via and the second conductive landing via vertically overlap the opening, and
the dummy insulating pillar does not vertically overlap the opening.

17. The semiconductor device as claimed in claim 12, wherein:
the dummy through hole has a bottom recessed from the upper surface of the common source plate,
the dummy insulating pillar fills the bottom of the dummy through hole, and
a bottom surface of the dummy insulating pillar is at a level lower than the upper surface of the common source plate.

18. The semiconductor device as claimed in claim 12, wherein:
the first conductive through-via has a first height in the first direction,
the dummy insulating pillar has a second height in the first direction, and
the second height is greater than or equal to 90 % of the first height and less than 100 % of the first height.

19. An electronic system, comprising:
a main board;
a semiconductor device on the main board; and
a controller electrically connected to the semiconductor device on the main board,
wherein the semiconductor device includes:
a substrate including a first region, a second region, and a third region,
a peripheral circuit structure on the substrate, the peripheral circuit structure including a peripheral circuit and a plurality of wiring layers connected to the peripheral circuit,
a common source plate on the peripheral circuit structure and extending in a horizontal direction,
gate electrodes on the common source plate on the first region and the second region, spaced apart from each other in a first direction perpendicular to an upper surface of the substrate, and having a stair shape on the second region,
a channel structure extending in the first direction through the gate electrodes on the first region,
a first conductive through-via penetrating the common source plate on the third region and electrically connected to the plurality of wiring layers, and
a dummy insulating pillar adjacent to the first conductive through-via on the third region and connected to an upper surface of the common source plate.

20. The electronic system as claimed in claim 19, further comprising a first conductive landing via surrounding a bottom sidewall of the first conductive through-via and on a first wiring layer of the plurality of wiring layers,
wherein the first conductive landing via is connected to the peripheral circuit through the first wiring layer.
